(19) United States
(12) Patent Application Publication
(10) Pub. No.: US 2023/0107549 A1
(43) Pub. Date: Apr. 6, 2023

(54) TIME MEASURING DEVICE, TIME MEASURING METHOD, AND DISTANCE MEASURING DEVICE

(71) Applicant: SONY SEMICONDUCTOR SOLUTIONS CORPORATION, KANAGAWA (JP)

(72) Inventors: TAKAYUKI ABE, KANAGAWA (JP); MASASHI SAITO, KANAGAWA (JP); TAKAHIRO SONODA, KUMAMOTO (JP)

(21) Appl. No.: 17/792,346

(22) PCT Filed: Jan. 8, 2021
(86) PCT No.: PCT/JP2021/000433

§ 371 Date: Jul. 12, 2022

(30) Foreign Application Priority Data
Jan. 20, 2020 (JP) 2020-007119

(51) Int. Cl. G04F 10/00; G01S 7/4865; G01S 17/894

(52) U.S. Cl. CPC G04F 10/005; G01S 7/4865; G01S 17/894

(57) ABSTRACT

There is provided a time measuring device including: a first counter unit (204) that acquires a difference time between a first measured signal and a second measured signal as a first measurement result by counting on the basis of a reference clock signal; a delay signal generation unit (208) that generates a delay signal by delaying the first measured signal on the basis of the first measurement result fed back from the first counter unit; a measurement unit (210) that measures a difference time between the delay signal and the second measured signal as a second measurement result; and an operation unit (212) that performs an operation by using the first measurement result and the second measurement result.

### TECHNICAL FIELD

The present disclosure relates to a time measuring device, a time measuring method, and a distance measuring device.

### BACKGROUND ART

As a method for measuring a distance to an object, a Time of Flight (ToF) sensor (distance measuring device) is known. For example, in a case where the ToF sensor is an indirect TOF sensor, the ToF sensor irradiates an object with irradiation light having a predetermined cycle, and detects a phase difference between the irradiation light and reflected light reflected from the object, so that the distance to the object can be measured. Although improvement in distance measurement accuracy is required for such a distance measuring device, there is a limit to improvement in distance measurement accuracy of the distance measuring device.

Therefore, in order to improve the distance measurement accuracy, it is conceivable to measure a time error (for example, a time difference or the like generated between control signals) generated in the distance measuring device by the time measuring device and to correct the distance measuring device on the basis of the measurement result. For example, as a time measuring device that measures such a minute time, a device disclosed in Patent Document 1 below can be exemplified.

### CITATION LIST

### Patent Document

Patent Document 1: Japanese Patent Application Laid-Open No. 05-150056

Patent Document 2: Japanese Patent Application Laid-Open No. 2011-254246

### SUMMARY OF THE INVENTION

### Problems to be Solved by the Invention

However, in the time measuring device disclosed in Patent Document 1 described above, since the resolution of the measurement time is limited, there is a limit in improving the distance measurement accuracy of the distance measuring device even in a case where correction is performed on the distance measuring device using the time measuring device.

Therefore, the present disclosure proposes a time measuring device and a time measuring method having further improved time resolution, and a distance measuring device using the same.

### Solutions to Problems

According to the present disclosure, there is provided a time measuring device including: a first counter unit that acquires a difference time between a first measured signal and a second measured signal as a first measurement result by counting on the basis of a reference clock signal; a delay signal generation unit that generates a delay signal by delaying the first measured signal on the basis of the first measurement result fed back from the first counter unit; a measurement unit that measures a difference time between the delay signal and the second measured signal as a second measurement result; and an operation unit that performs an operation by using the first measurement result and the second measurement result.

Furthermore, according to the present disclosure, there is provided a time measuring method including: acquiring a difference time between a first measured signal and a second measured signal as a first measurement result by counting on the basis of a reference clock signal; generating a delay signal by delaying the first measured signal on the basis of the first measurement result that has been fed back; measuring a difference time between the delay signal and the second measured signal as a second measurement result; and performing an operation by using the first measurement result and the second measurement result.

Moreover, according to the present disclosure, there is provided a distance measuring device that is a ToF distance measuring device including a time measuring device, the time measuring device including: a first counter unit that acquires a difference time between a first measured signal and a second measured signal as a first measurement result by counting on the basis of a reference clock signal; a delay signal generation unit that generates a delay signal by delaying the first measured signal on the basis of the first measurement result fed back from the first counter unit; a measurement unit that measures a difference time between the delay signal and the second measured signal as a second measurement result; and an operation unit that performs an operation by using the first measurement result and the second measurement result.

### BRIEF DESCRIPTION OF DRAWINGS

FIG. 1 is a block diagram illustrating a configuration example of a distance measuring device 1 according to an embodiment of the present disclosure.

FIG. 2 is an explanatory diagram for explaining the principle of a distance calculation method using the distance measuring device 1 according to the embodiment of the present disclosure.

FIG. 3 is an explanatory diagram for explaining a phase error θ.

FIG. 4 is a circuit block diagram illustrating a configuration example of a TV conversion circuit including an ADC.

FIG. 5 is a timing chart (part 1) illustrating a change example of an output signal of the TV conversion circuit of FIG. 4.

FIG. 6 is an example of a timing chart of a comparative example.

FIG. 7 is a flowchart for explaining a time measuring method of a TDC 200 according to a first embodiment of the present disclosure.

FIG. 8 is an explanatory diagram for explaining a configuration example of the TDC 200 according to the first embodiment of the present disclosure.

FIG. 9 is an example of a timing chart of the TDC 200 according to the first embodiment of the present disclosure.

FIG. 10 is an explanatory diagram for explaining a terminal to be measured of the TDC 200 according to the first embodiment of the present disclosure.

FIG. 11 is an explanatory diagram (part 1) for explaining an example of a delay signal generation unit 208 according to the first embodiment of the present disclosure.

FIG. 12 is an explanatory diagram (part 2) for explaining an example of the delay signal generation unit 208 according to the first embodiment of the present disclosure.

FIG. 13 is an explanatory diagram (part 3) for explaining an example of the delay signal generation unit 208 according to the first embodiment of the present disclosure.

FIG. 14 is an explanatory diagram (part 4) for explaining an example of the delay signal generation unit 208 according to the first embodiment of the present disclosure.

FIG. 15 is an explanatory diagram (part 5) for explaining an example of the delay signal generation unit 208 according to the first embodiment of the present disclosure.

FIG. 16 is an explanatory diagram (part 6) for explaining an example of the delay signal generation unit 208 according to the first embodiment of the present disclosure.

FIG. 17 is a flowchart (part 2) for explaining a time measuring method of a TDC 200 according to a first embodiment of the present disclosure.

FIG. 18 is an explanatory diagram for explaining a configuration example of a TDC 200 according to a second embodiment of the present disclosure.

FIG. 19 is an explanatory diagram for explaining a configuration example of a TAC 500 according to the second embodiment of the present disclosure.

FIG. 20 is an example of a timing chart of the TAC 500 according to the second embodiment of the present disclosure.

FIG. 21 is an example of a timing chart of a TAC 500 according to a modification of the second embodiment of the present disclosure.

FIG. 22 is a flowchart for explaining a calibration method according to a third embodiment of the present disclosure.

FIG. 23 is an explanatory diagram (part 1) for explaining the calibration method according to the third embodiment of the present disclosure.

FIG. 24 is an explanatory diagram (part 2) for explaining the calibration method according to the third embodiment of the present disclosure.

FIG. 25 is an explanatory diagram for explaining a configuration example of an ADC 700 according to a fourth embodiment of the present disclosure.

### MODE FOR CARRYING OUT THE INVENTION

Preferred embodiments of the present disclosure will be described in detail below with reference to the accompanying drawings. Note that, in the present specification and the drawings, the same reference numerals are given to the constituent elements having substantially the same functional configuration, and redundant explanations are omitted.

Furthermore, in this specification and the drawings, a plurality of constituent elements having substantially the same or similar functional configuration may be distinguished by attaching different numerals after the same reference numerals. However, in a case where it is not necessary to particularly distinguish each of a plurality of constituent elements having substantially the same or similar functional configuration, only the same reference numerals are attached. Furthermore, similar constituent elements of different embodiments may be distinguished by adding different alphabets after the same reference numerals. However, in a case where it is not necessary to particularly distinguish each of similar constituent elements, only the same reference numerals are attached.

In the following description, a substantially rectangular shape is not limited to a geometrically perfect rectangular shape, and includes a shape in which corners of the rectangular shape are somewhat rounded (curved) to an allowable extent in the operation of the time measuring device and a shape similar to the shape.

Furthermore, in the following description, “connection” means electrically connecting a plurality of elements, unless otherwise noted in the description of the circuit configuration. Moreover, “connection” in the following description includes not only a case of directly and electrically connecting a plurality of elements but also a case of indirectly and electrically connecting via other elements.

Note that the description will be given in the following order.

1. Overview of distance measuring device 1

2. Principle of distance calculation method using distance measuring device 1

3. Background to creation of embodiments according to the present disclosure by the present inventors

4. First embodiment

4.1 Overview

4.2 Delay signal generation unit 208

4.3 Time measuring method

5. Second embodiment

5.1 Configuration example of TDC 200

5.2 Configuration example of TAC 500

5.3 Configuration example of TAC 500

5.4 Modification

6. Third embodiment

7. Fourth embodiment

8. Conclusion

9. Supplement

### 1. Overview of Distance Measuring Device 1

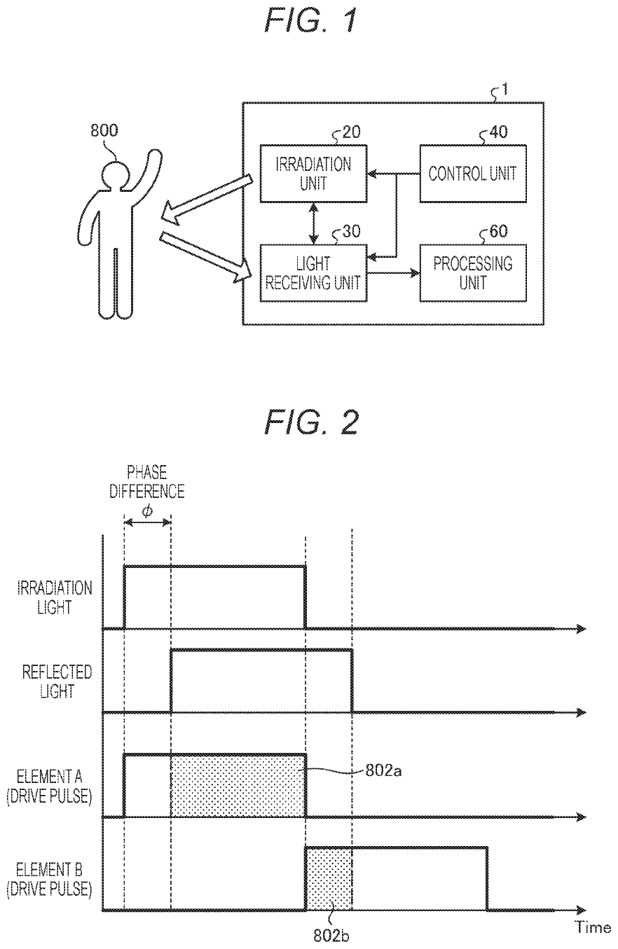

First, a schematic configuration of a distance measuring device 1 according to an embodiment of the present disclosure will be described with reference to FIG. 1. FIG. 1 is a block diagram illustrating a configuration example of the distance measuring device 1 according to the embodiment of the present disclosure. The distance measuring device 1 according to the embodiment of the present disclosure is an indirect time of flight (ToF) sensor. Specifically, the distance measuring device 1 irradiates an object with irradiation light having a predetermined cycle, and detects a phase difference between the irradiation light and reflected light from the object, so that the distance to the object can be measured. More specifically, as illustrated in FIG. 1, the distance measuring device 1 can mainly include an irradiation unit 20, a light receiving unit 30, a control unit 40, and a processing unit 60. Each functional block included in the distance measuring device 1 according to the present embodiment will be described below.

(Irradiation Unit 20)

The irradiation unit 20 includes a laser light source (not illustrated). The wavelength of the emitted light can be changed by appropriately selecting the light source. Note that, in the present embodiment, the description will be given assuming that the irradiation unit 20 emits infrared light having a wavelength in a range of 780 nm to 1000 nm, for example, but in the present embodiment, the irradiation unit 20 is not limited to a configuration of emitting such infrared light. Furthermore, the irradiation unit 20 can irradiate an object 800 with irradiation light whose brightness in a cyclic manner varies in synchronization with a signal (drive pulse) supplied from the control unit 40 as described later.

(Light Receiving Unit 30)

The light receiving unit 30 receives the reflected light reflected from the object 800. The light receiving unit 30 includes a condenser lens (not illustrated) and a plurality of light receiving elements (pixels) (not illustrated) as described later. The condenser lens has a function of collecting received light to each light receiving element 10. Furthermore, the light receiving element generates a charge (for example, an electron) on the basis of the intensity of the received light, converts the generated charge into a signal in synchronization with a signal (drive pulse) supplied from the control unit 40 as described later, and transfers the signal to the processing unit 60.

(Control Unit 40)

The control unit 40 supplies a cyclic signal (drive pulse) to the irradiation unit 20 and the light receiving unit 30, and controls the irradiation timing of the irradiation light and the drive timing of the light receiving unit 30.

(Processing Unit 60)

The processing unit 60 can acquire the signal from the light receiving unit 30 and acquire the distance to the object 800 by, for example, an indirect ToF (iToF) method on the basis of the acquired signal. Note that a method of calculating the distance will be described later.

### 2. Principle of Distance Calculation Method Using Distance Measuring Device 1

Next, a principle of a distance calculation method (indirect type) using the distance measuring device 1 according to the embodiment of the present disclosure will be described with reference to FIG. 2. FIG. 2 is an explanatory diagram for explaining the principle of the distance calculation method using the distance measuring device 1 according to the embodiment of the present disclosure. Specifically, FIG. 2 schematically illustrates temporal variation of intensities of irradiation light and reflected light in the distance measuring device 1 and a drive signal of the light receiving unit 30.

As illustrated in FIG. 2, the distance measuring device 1 irradiates the object 800 with light modulated so that the intensity of light varies in a cyclic manner from the irradiation unit 20. The emitted light is reflected by the object 800 and detected as reflected light by the light receiving unit 30 of the distance measuring device 1. As illustrated in FIG. 2, the detected reflected light (the second row from the top in FIG. 2) has a phase difference φ with respect to the irradiation light (the first row from the top in FIG. 2), and the phase difference φ increases as the distance from the distance measuring device 1 to the object 800 increases and decreases as the distance from the distance measuring device 1 to the object 800 decreases. That is, since the phase difference φ and the distance from the distance measuring device 1 to the object 800 have a predetermined relationship, in the present embodiment, the distance from the distance measuring device 1 to the object 800 can be obtained by detecting the phase difference φ.

Therefore, in the light receiving unit 30 according to the present embodiment, for example, a drive signal (specifically, a drive pulse) is imparted to the two elements A and B (for example, a light receiving element or a memory element) provided for each pixel unit, the drive signal differentially driving (driving in different periods) the two elements A and B. For example, it is assumed that a drive signal imparted to the element A is illustrated in the third row from the top in FIG. 2, a drive signal imparted to the element B is illustrated in the fourth row from the top in FIG. 2, and these elements A and B operate in a period having a convex upward. Then, as indicated by the shape of the drive signal in FIG. 2, the periods during which these elements A and B operate do not overlap, and thus, it is understood that these elements A and B are driven differentially from each other.

Moreover, as illustrated in FIG. 2, in a case where the reflected light has a phase difference φ with respect to the irradiation light, each of the elements A and B receives the reflected light in each period of regions 802a and 802b indicated by gray in FIG. 2, and generates and accumulates charges. In other words, each of the elements A and B acquires the light reception signal corresponding to the area of the region 802a and the region 802b in FIG. 2. Then, as is clear from FIG. 2, the difference between the light reception signal amount (corresponding to the area of the region 802a) in the element A and the light reception signal amount (corresponding to the area of the region 802b) in the element B changes according to the phase difference cp. Accordingly, in the present embodiment, the distance can be calculated by calculating the difference between the light reception signal amounts of the elements A and B and calculating the phase difference φ on the basis of the calculated difference. Note that, in the present embodiment, the distance may be calculated by calculating the phase difference φ using the ratio of the light reception signal amount instead of the difference of the light reception signal amount.

### 3. Background to Creation of Embodiments According to the Present Disclosure by the Present Inventors

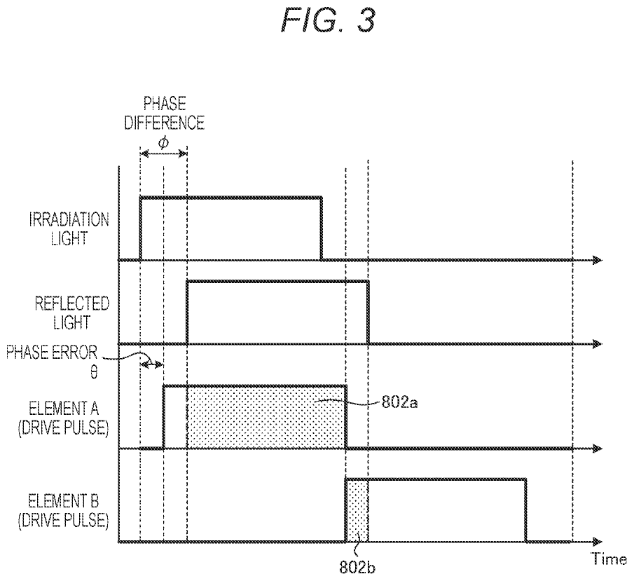

Next, before describing the details of the embodiments according to the present disclosure, a background in which the present inventors have created the embodiments according to the present disclosure will be described with reference to FIGS. 2 and 3. FIG. 3 is an explanatory diagram for explaining a phase error θ, and each row in FIG. 3 corresponds to each row in FIG. 2.

In the distance measuring device 1, as described above, the control unit 40 supplies a cyclic signal (drive pulse) to the irradiation unit 20 and the light receiving unit 30 (specifically, the element A and the element B), and controls the irradiation timing of the irradiation light and the drive timing of the light receiving unit 30. For example, as illustrated in FIG. 2, the control unit 40 imparts a drive signal synchronized with a signal imparted to the irradiation unit 20 (a drive signal having intensity of irradiation light and a temporal variation illustrated in the first row from the top in FIG. 2) to the element A of the light receiving unit 30 so that the element A of the light receiving unit 30 operates to be synchronized with the irradiation unit 20. Moreover, the control unit 40 imparts a drive signal having a timing different from that of the drive signal imparted to the element A to the element B so that the element B of the light receiving unit 30 is driven differentially from the element A. Note that, in the present embodiment, the signal imparted to the element A of the light receiving unit 30 may not be synchronized with the drive signal imparted to the irradiation unit 20, and is not particularly limited as long as it is a signal having a fixed and known predetermined phase difference with respect to the drive signal imparted to the irradiation unit 20.

As described above, the distance measuring device 1 is required to further improve the distance measurement accuracy. However, according to the study of the present inventors, there is a limit to improvement of distance measurement accuracy due to the presence of an error as described below. Specifically, due to a variation in voltage of the control unit 40, a power supply (not illustrated), or the like, or a variation in device temperature, for example, as illustrated in FIG. 3, a drive signal imparted to the element A of the light receiving unit 30 may have an unintended phase difference θ (phase error θ) with respect to the drive signal imparted to the irradiation unit 20. In other words, the drive signal imparted to the element A of the light receiving unit 30 has a phase error θ that varies due to voltage variation or temperature variation. As described above, in the distance measuring device 1, the distance is calculated by calculating the phase difference φ between the irradiation light and the reflected light corresponding to the difference or the ratio of the light reception signal amounts of the elements A and B. Therefore, since the relationship between the phase difference φ and the distance varies due to the generation of the phase error θ described above due to voltage variation or temperature variation, the phase difference φ cannot be correctly calculated from the difference in the light reception signal amount or the like in the distance measuring device 1. As a result, in the distance measuring device 1, since the phase difference φ cannot be correctly calculated, a distance measurement error occurs. That is, since the drive signal imparted to the element A of the light receiving unit 30 has the phase error θ due to the voltage variation and the temperature variation, a distance measurement error occurs, and thus, there is a limit in improving the distance measurement accuracy of the distance measuring device 1.

Then, in view of such a situation, the present inventors have uniquely conceived of suppressing the occurrence of a distance measurement error, that is, improving the distance measurement accuracy by detecting the phase error θ described above and performing correction using the detected phase error θ. Then, for this purpose, a time to digital converter (TDC) that measures the phase error θ described above with high accuracy, in other words, with high resolution (for example, 10 ps or less) is required. More specifically, if the correction can be performed by such a phase error θ measured by the high-resolution TDC, the distance measurement error can be suppressed to several mm or less, for example.

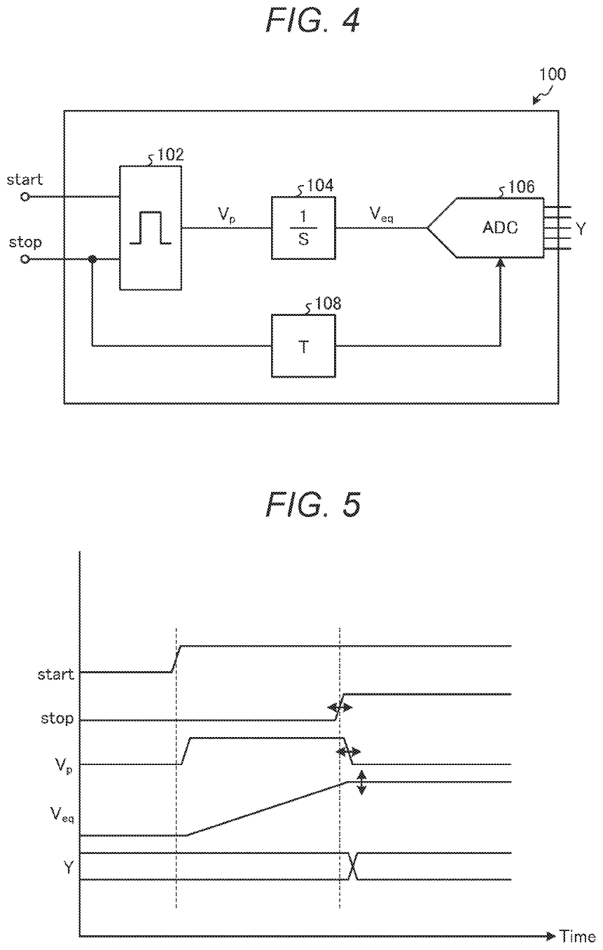

Therefore, the present inventors have conducted intensive studies on the high-resolution TDC. Here, with reference to FIGS. 4 and 5, a TV conversion circuit (Time to Voltage Converter) (time-voltage conversion circuit) 100, which is one of the components of the TDC, will be considered. FIG. 4 is a circuit block diagram illustrating a configuration example of the TV conversion circuit 100 including an analog to digital converter (ADC) (analog-digital conversion circuit) 106, and FIG. 5 is a timing chart illustrating a change example of an output signal of the TV conversion circuit 100 in FIG. 4.

The TDC is a measurement target of a difference between a rise time or a fall time of a signal (start) that arrives early and a signal (stop) that arrives late, which are signals of a wave that is substantially rectangular (substantially rectangular wave) or signals (toggle signals) that repeats a substantially rectangular wave in a cyclic manner. As illustrated in FIGS. 4 and 5, the TV conversion circuit 100 includes a pulse generator 102 that converts a difference between a rise time or a fall time of a signal (start) that arrives early and a signal (stop) that arrives late into a measured pulse Vₚ. Moreover, the TV conversion circuit 100 includes an integrator 104 that converts the pulse width Tᵥₚ of the measured pulse Vₚ into a voltage V_{eq}, an ADC 106 that converts the converted voltage V_{eq}, into a digital code Y, and a delay device 108. Then, when the integrator 104 is ideally configured, an integral slope S of the integrator 104 takes a constant value, so that the voltage V_{eq} according to the pulse width Tᵥₚ of the measured pulse Vₚ is obtained. Accordingly, the pulse width Tᵥₚ can be calculated by reading the voltage V_{eq} by the ADC 106 and dividing the voltage V_{eq} by the known integral slope S (see Equation (1)).

$$\begin{matrix}[ Math . 1 ] & \\ {T}_{vp} = \frac{{V}_{eq}}{S} & ( 1 )\end{matrix}$$

Moreover, the reading accuracy of the voltage V_{eq} by the ADC 106 is determined by the effective bit depth N of the ADC 106 as can be seen from the following Equation (2). Note that, in the following Equation (2), Vₘₐₓ−Vₘᵢₙ means a variation range of the voltage V_{eq} input to the ADC 106.

$$\begin{matrix}[ Math . 2 ] & \\ {V}_{eq}^{′} = \frac{Y * ( {V}_{max} - {V}_{min} )}{{2}^{N}} & ( 2 )\end{matrix}$$

Accordingly, according to the Equations (1) and (2), the pulse width Tᵥₚ, that is, the measurement accuracy of the time to be measured can be expressed by the following Equation (3).

$$\begin{matrix}[ Math . 3 ] & \\ {T}_{vp} = \frac{Y * ( {V}_{max} - {V}_{min} )}{{2}^{N} * S} & ( 3 )\end{matrix}$$

Accordingly, the measurement accuracy of the time to be measured of the TDC is reduced by reducing the variation range Vₘₐₓ−Vₘᵢₙ of the voltage (V_{eq}) input to the ADC 106. Furthermore, the measurement accuracy of the time to be measured by the TDC is also reduced by increasing the effective bit depth N.

Furthermore, the Equation (3) can be converted into the following Equation (4).

$$\begin{matrix}[ Math . 4 ] & \\ {T}_{vp}^{′} = \frac{Y * ( {T}_{max} - {T}_{min} )}{{2}^{N}} & ( 4 )\end{matrix}$$

That is, as can be seen from Equation (4), the measurement accuracy of the time to be measured of the TDC can also be reduced by reducing the pulse width Tᵥₚ of the measured pulse Vₚ output from the pulse generator 102 and increasing the effective bit depth N. In other words, the time resolution of the TDC can be improved by reducing the pulse width Tᵥₚ of the measured pulse Vₚ output from the pulse generator 102 and increasing the effective bit depth N. Note that the maximum value of the pulse width Tᵥₚ of the measured pulse Vₚ is the maximum value of the difference between the rise time or the fall time of the signal (start) that arrives early and the signal that arrives late (stop), and is the measurement range of the TDC.

However, in order to improve the time resolution of the TDC, it is conceivable to increase the effective bit depth N of the ADC 106. However, in a case where the TDC is to be manufactured by a miniaturization process in which a low operating voltage is required, there is a limit to increasing the effective bit depth N of the ADC 106. Furthermore, in order to improve the time resolution of the TDC, it is conceivable to reduce the maximum value of the difference between the rise time or the fall time of the signal (start) that arrives early and the signal (stop) that arrives late. However, this means narrowing the measurement range of the TDC, and thus it cannot be said to be a preferable solution. That is, it can be said that it is difficult to improve the time resolution of the TDC without narrowing the measurement range of the TDC since these are in a trade-off relationship.

Therefore, as one means for improving the time resolution without narrowing the measurement range of the TDC, for example, the technology disclosed in Patent Document 1 described above can be mentioned. Patent Document 1 discloses a technology of coarsely measuring (counting) an entire measurement range of a TDC in a clock cycle by a counter, and measuring a part of the measurement range described above with a resolution equal to or less than the clock cycle by a TV conversion circuit. Note that, in the following description, the technology disclosed in Patent Document 1 described above is referred to as a comparative example.

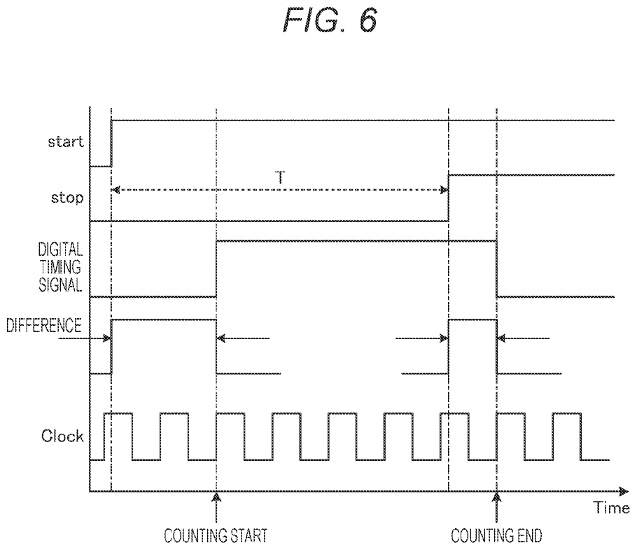

The comparative example will be described below with reference to FIG. 6. FIG. 6 is an example of a timing chart of the comparative example. In the comparative example, in a case of measuring the measured signal (signal having the time width T) (specifically, for example, the time difference between the rise times of the start signal and the stop signal illustrated in FIG. 6), first, the measured signal is converted into a digital timing signal on the basis of a reference clock signal (note that the example of FIG. 6 assumes a case where a commonly used double flip flop synchronizer is used). As illustrated in FIG. 6, the digital timing signal is a signal obtained by tapping the measured signal at the rising timing of the reference clock signal in every clock cycle of the reference clock signal (that is, coarse measurement is performed in the clock cycle). Moreover, the time width T of the measured signal can be measured by cutting out a difference (input pulse signal) between the measured signal and the digital clock signal, measuring the cut out difference with the TV conversion circuit, and subtracting the measured difference from the digital timing signal.

As a result, in the comparative example, since the measurement range of the TDC and the width of the pulse signal input to the TV conversion circuit can be separated, the width of the pulse signal input to the TV conversion circuit can be narrowed without narrowing the measurement range of the TDC. Then, in the comparative example, since the pulse signal width input to the TV conversion circuit can be narrowed, the time resolution is improved. Accordingly, according to the comparative example, the time resolution of the TDC can be improved without narrowing the measurement range of the TDC.

However, according to the study of the present inventors, in the comparative example, since the difference between the measured signal and the digital clock signal may be the integration of the clock cycle and the width equal to or less than the clock cycle as illustrated in FIG. 6, the width of the input pulse signal that can be measured by the TV conversion circuit needs to be set to be equal to or greater than the clock cycle. As a result, in the comparative example, since it is necessary to increase the maximum value of the width of the pulse signal input to the TV conversion circuit, there is a limit in improving the time resolution of the TDC.

That is, since the TDC according to the comparative example has a limit in improving the time resolution, there is a limit in improving the distance measurement accuracy even if the distance measuring device 1 is corrected using the TDC. Therefore, the present inventors have intensively studied to obtain the TDC with further improved temporal resolution. As a result, the present inventors have created the TDC according to the embodiment of the present disclosure capable of improving the time resolution of the TDC without narrowing the measurement range of the TDC. Details of such embodiments according to the present disclosure will be sequentially described below.

### 4. First Embodiment

### 4.1 Overview

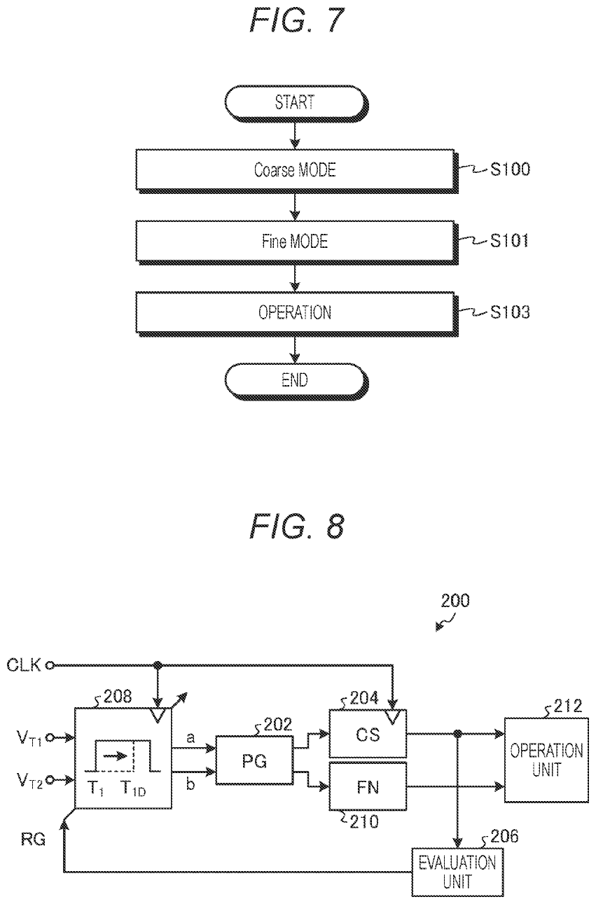

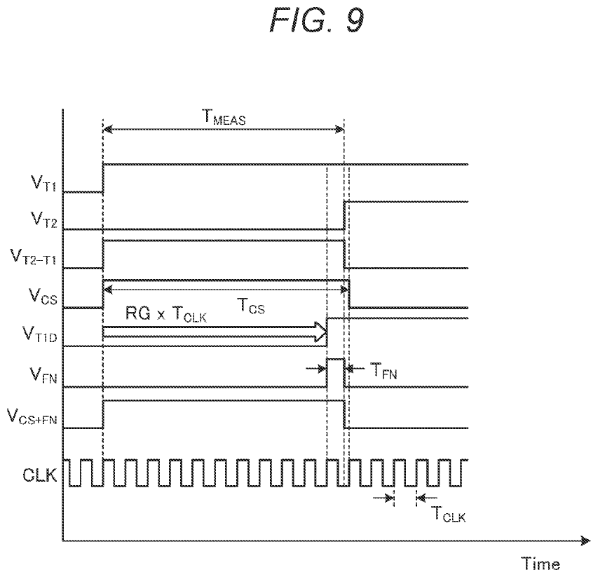

First, an overview of a first embodiment of the present disclosure will be described with reference to FIGS. 7 to 9. FIG. 7 is a flowchart for explaining a time measuring method of a TDC 200 according to the first embodiment of the present disclosure. Furthermore, FIG. 8 is an explanatory diagram for explaining a configuration example of the TDC 200 according to the first embodiment of the present disclosure, and FIG. 9 is an example of a timing chart of the TDC 200 according to the first embodiment of the present disclosure.

In the first embodiment of the present disclosure created by the present inventors, as illustrated in FIG. 7, as similar to the comparative example, a Coarse mode in which the entire measurement range of the TDC is coarsely measured by a counter in a clock cycle T_{CLK} (see FIG. 9) is performed (step S100), then, a Fine mode in which the measurement is performed in detail is performed (step S101), and further, operation is performed on the basis of the measurement results in these two modes (step S103). In other words, in the present embodiment, the time measurement is roughly divided into three steps, and these steps to be performed include two types of measurement modes.

Specifically, as illustrated in FIG. 8, the TDC 200 according to the first embodiment of the present disclosure mainly includes a pulse generator 202, a Coarse measurement unit (first counter unit) 204, a delay evaluation unit 206, a delay signal generation unit 208, a fine measurement unit (measurement unit) 210, and an operation unit 212. Each component of the TDC 200 will be sequentially described below.

(Pulse Generator 202)

The pulse generator 202 includes a logic circuit, and in step S100 described above, a difference between rise times or fall times (a difference time between the first measured signal and the second measured signal) of the measured signals V_{T1} and V_{T2} (first measured signal, second measured signal) (see FIG. 9), which are two waves having a substantially rectangular shape (substantially rectangular waves) or signals (toggle signals) repeating the substantially rectangular waves in a cyclic manner, is converted into a measured pulse V_{T2-T1} (see FIG. 9) and is output to the Coarse measurement unit 204 as described later. Note that the width of the measurement target pulse V_{T2-T1} is a measurement target of the TDC 200. Accordingly, the signal (start) that arrives early described above corresponds to the measured signal V_{T1}, and the signal (stop) that arrives late corresponds to the measured signal V_{T2}.

Furthermore, in step S101 described above, the pulse generator 202 converts a difference in rise time or fall time between the delay signal V_{T1D} (see FIG. 9) output from the delay signal generation unit 208 as described later and the measured signal V_{T2} (see FIG. 9) described above into a difference V_{FN} (see FIG. 9) that is a substantially rectangular wave, and outputs the difference V_{FN} to the fine measurement unit 210 as described later. Note that, although details will be described later, in the present embodiment, in the Fine mode for fine measurement, the difference V_{FN} between the delay signal V_{T1D} and the above-described measured signal V_{T2} is measured instead of measuring the difference (input pulse signal) between the measured signal and the digital clock signal as in the comparative example.

(Coarse Measurement Unit 204)

The Coarse measurement unit 204 includes a counter circuit (logic circuit), and can count the number of clocks of the reference clock signal CLK (see FIG. 9). Specifically, in step S100 described above, the Coarse measurement unit 204 obtains the measured pulse V_{T2-T1} in increments of a clock cycle T_{CLK} (see FIG. 9) of the reference clock signal CLK, generates a digital timing signal V_{CS} (see FIG. 9), and counts (coarsely measures) the digital timing signal V_{CS} in the clock cycle T_{CLK}. Then, the Coarse measurement unit 204 outputs the count result (first measurement result) thus obtained to the delay evaluation unit 206 and the operation unit 212 as described later.

(Delay Evaluation Unit 206)

The delay evaluation unit 206 determines a delay amount (RG value) using the count result of the Coarse measurement unit 204, and feeds back the delay amount to the delay signal generation unit 208 as described later. In the present embodiment, the delay amount (RG value) is set to increase in proportion to the width of the measured pulse V_{T2-T1} (see FIG. 9) (in other words, the delay amount (RG value) follows the width of the measured pulse V_{T2-T1}).

(Delay Signal Generation Unit 208)

The delay signal generation unit 208 generates a delay signal V_{T1D} (see FIG. 9) by delaying the above-described measured signal V_{T1} (see FIG. 9) on the basis of the delay amount (RG value) fed back from the delay evaluation unit 206. More specifically, the delay signal generation unit 208 delays the measured signal V_{T1} by a numerical value obtained by multiplying the delay amount (RG value) by the reference clock cycle T_{CLK} (see FIG. 9). Then, the delay signal generation unit 208 outputs the generated delay signal V_{T1D} to the pulse generator 202 described above. Furthermore, the delay signal generation unit 208 can also generate a calibration signal for calibrating the TDC 200. Note that details of the calibration will be described later.

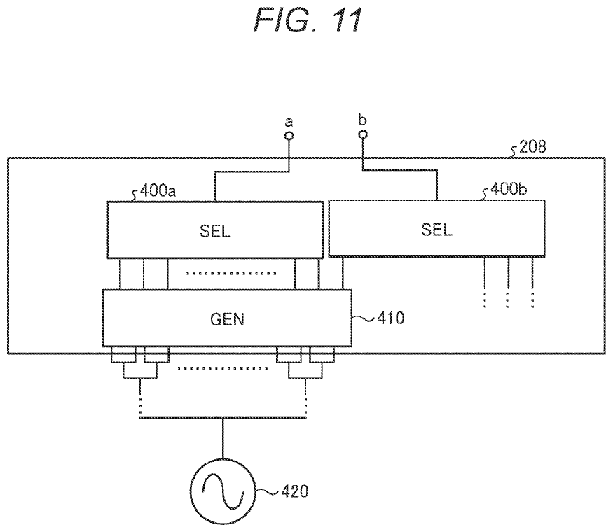

Then, the delay signal generation unit 208 may include, for example, a plurality of flip-flop circuits (not illustrated) arranged in a line and evenly on a semiconductor substrate (not illustrated). Alternatively, the delay signal generation unit 208 may include, for example, a plurality of latch circuits (not illustrated) arranged in a line and evenly on a semiconductor substrate (not illustrated). Moreover, the plurality of flip-flop circuits or latch circuits may be electrically connected to, for example, wiring branched in a tournament form from the reference clock signal source 420 (for example, including a phase locked loop (PLL) or the like) (see FIG. 11), and the reference clock signal CLK is equally transmitted to each of the flip-flop circuits or the latch circuits by the wiring. Note that details of the circuit configuration of the delay signal generation unit 208 will be described later.

(Fine Measurement Unit 210)

The fine measurement unit 210 can be configured by, for example, the TV conversion circuit 100 including the ADC 106 as illustrated in FIG. 4, and performs the fine mode for fine measurement in step S101 described above. Specifically, the fine measurement unit 210 measures the difference VFN output from the pulse generator 202 with high resolution, and outputs a measurement result (second measurement result) to the operation unit 212 as described later. Note that, since the measurement method has already been described with reference to FIGS. 4 and 5, the description thereof will be omitted here. In the present embodiment, the fine measurement unit 210 measures the difference V_{FN} between the delay signal V_{T1D} and the above-described measured signal V_{T2} instead of measuring the difference (input pulse signal) between the measured signal and the digital clock signal as in the comparative example.

Then, as described above, the delay signal V_{T1D} is generated by delaying the measured signal V_{T1} by a numerical value obtained by multiplying the delay amount (RG value) proportional to the width of the measured pulse V_{T2-T1} by the reference clock cycle T_{CLK}. Then, the difference V_{FN} to be measured by the fine measurement unit 210 is a difference between the V_{T1D} and the measured signal V_{T2} generated in this manner, and thus has a width equal to or less than the reference clock cycle T_{CLK}. Accordingly, since the measurement range of the fine measurement unit 210 which is the TV conversion circuit 100 can be narrowed to a width equal to or less than the reference clock cycle T_{CLK}, the time resolution of the fine measurement unit 210 can be improved. As a result, in the present embodiment, the time resolution of the TDC 200 can be improved.

(Operation Unit 212)

The operation unit 212 includes a logic circuit, a memory, and the like, and uses the count result (first measurement result) of the Coarse measurement unit 204 and the measurement result (second measurement result) of the fine measurement unit 210 described above to perform an operation of the difference between the rise time and the fall time of the two measured signals V_{T1} and V_{T2} (first measured signal, second measured signal) (see FIG. 9) (the difference time between the first measured signal and the second measured signal).

Note that, in the present embodiment, the components included in the TDC 200 are not limited to the components illustrated in FIG. 8, and may include other components.

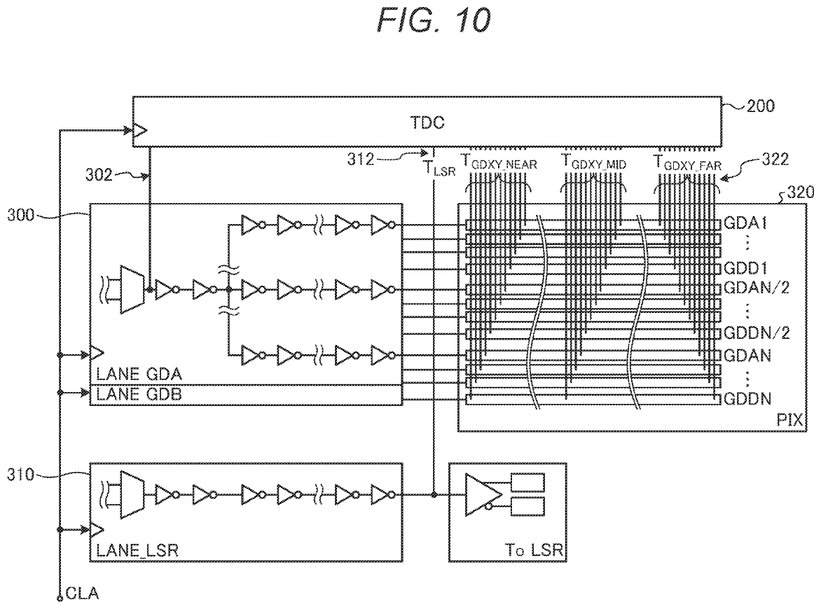

Details of the time measuring method performed by the TDC 200 according to the present embodiment will be described with reference to FIGS. 8 and 10.

First, in the present embodiment, the pulse generator 202 converts the difference between the rise time or the fall time of the two measured signals V_{T1} and V_{T2} into a measured pulse V_{T2-T1} illustrated in the third row from the top in FIG. 9, and outputs the measured pulse V_{T2-T1} to the Coarse measurement unit 204. Next, the Coarse measurement unit 204 obtains the measured pulse V_{T2-T1}described above in increments of a clock cycle T_{CLK} of the reference clock signal CLK, generates a digital timing signal V_{CS} illustrated in the fourth row from the top in FIG. 9, and counts (coarsely measures) the digital timing signal V_{CS} in the clock cycle T_{CLK} (step S100).

Moreover, in the present embodiment, the delay evaluation unit 206 determines a delay amount (RG value) using the count result of the Coarse measurement unit 204, and feeds back the delay amount to the delay signal generation unit 208. For example, the delay evaluation unit 206 determines the delay amount (RG value) on the basis of the count result with reference to the following Equation (5).

[Math. 5]

RG=CNT−(Nₚ+1) (5)

Note that, in Equation (5), the CNT indicates the count result in the Coarse measurement unit 204, that is, the number of counts obtained by counting the digital timing signal V_{CS} in the clock cycle (T_{CLK}). Furthermore, an arbitrary integer can be used as the constant Nₚ, and for example, in the example illustrated in FIG. 9, the constant Nₚ is set to 0. As can be seen from Equation (5), in the present embodiment, the delay amount (RG value) is set to increase in proportion to the width of the measured pulse V_{T2-T1}.

Then, the delay signal generation unit 208 generates a delay signal V_{T1D} illustrated in the fifth row from the top in FIG. 9 by delaying the measured signal V_{T1} on the basis of the delay amount (RG value) fed back from the delay evaluation unit 206. More specifically, the delay signal generation unit 208 delays the measured signal V_{T1} by a numerical value obtained by multiplying the delay amount (RG value) by the reference clock cycle T_{CLK}, and outputs the generated delay signal V_{T1D} to the pulse generator 202 described above. Moreover, the pulse generator 202 converts the difference between the rise time or the fall time of the delay signal V_{T1D} output from the delay signal generation unit 208 and the above-described measured signal V_{T2} into the difference VFN illustrated in the sixth row from the top in FIG. 9, and outputs the difference to the fine measurement unit 210 (note that, in the example of FIG. 9, the difference in rise time is used).

Next, the fine measurement unit 210 measures the difference V_{FN} output from the pulse generator 202 with high resolution, and outputs a measurement result to the operation unit 212 (step S101). That is, in the present embodiment, the fine measurement unit 210 measures the difference V_{FN} between the delay signal V_{T1D} and the above-described measured signal V_{T2} instead of measuring the difference (input pulse signal) between the measured signal and the digital clock signal as in the comparative example. As described above, the delay signal V_{T1D} is generated by delaying the measured signal V_{T1} by a numerical value obtained by multiplying the delay amount (RG value) proportional to the width of the measured pulse V_{T2-T1} by the reference clock cycle T_{CLK} Then, the difference VFN to be measured by the fine measurement unit 210 is a difference between the V_{T1D} and the measured signal V_{T2} generated in this manner, and thus has a width equal to or less than the reference clock cycle T_{CLK} Accordingly, since the measurement range of the fine measurement unit 210 which is the TV conversion circuit 100 can be narrowed to a width equal to or less than the reference clock cycle T_{CLK}, the time resolution of the fine measurement unit 210 can be improved. As a result, in the present embodiment, the time resolution of the TDC 200 can be improved.

The operation unit 212 performs an operation of a difference between rise times or fall times of the two measured signals V_{T1} and V_{T2} by using the count result of the Coarse measurement unit 204 and the measurement result of the fine measurement unit 210 (step S103). Note that, in the example of FIG. 9, an operation of the difference between the rise times of the two measured signals V_{T1} and V_{T2} is performed. More specifically, the operation unit 212 performs an operation of the operation result V_{CS+FN} illustrated in the seventh row from the top in FIG. 9 on the basis of the following Equation (6).

$$\begin{matrix}[ Math . 6 ] & \\ \begin{matrix}{T}_{MEAS} = {T}_{CS} - ( {N}_{P} + 1 ) * {T}_{CLK} + {T}_{FN} \\ = \{ CNT - ( {N}_{P} + 1 ) \} * {T}_{CLK} + {T}_{FN} \\ = RG * {T}_{CLK} + {T}_{FN}\end{matrix} & ( 6 )\end{matrix}$$

In Equation (6), TMEAS is a difference between rise times or fall times of the two measured signals V_{T1} and V_{T2} to be measured, T_{CS} is a time width of the digital timing signal V_{CS} illustrated in the fourth row from the top in FIG. 9, and T_{FN} is a time width of the difference V_{FN} illustrated in the sixth row from the top in FIG. 9. That is, the operation result V_{CS+FN} in FIG. 9, which is the measurement target T_{MEAS}, can be obtained by integrating the time width of the difference V_{FN}, which is the measurement result of the fine measurement unit 210, with the multiplication result of the delay amount (RG) and the reference clock cycle T_{CLK} by the Equations (6) and (5). Note that the delay amount (RG) is determined on the basis of the count result of the Coarse measurement unit 204 as described above.

Here, a measurement target of the TDC 200 according to the present embodiment in the distance measuring device 1 will be specifically described with reference to FIG. 10. FIG. 10 is an explanatory diagram for explaining a terminal to be measured of the TDC 200 according to the present embodiment.

As illustrated in FIG. 10, the distance measuring device 1 includes, for example, a pixel drive pulse generator 300 that supplies a signal (drive pulse) for driving to a plurality of light receiving elements (pixels) of the light receiving unit 30 described above. Moreover, the distance measuring device 1 includes a laser drive pulse generator 310 that supplies a signal (drive pulse) for driving to the laser light source of the irradiation unit 20 described above, and a pixel unit 320 (light receiving unit 30) including a plurality of light receiving elements. In the present embodiment, the measured signal V_{T1} to be measured by the TDC 200 can be obtained, for example, by measuring the voltage of the output terminal 302 of the pixel drive pulse generator 300 described above. Furthermore, in the present embodiment, the plurality of measured signals V_{T2} to be measured by the TDC 200 can be obtained, for example, by measuring voltages of the output terminal 312 of the laser drive pulse generator 310 described above, an input terminal 322 of the pixel unit 320 described above, and the like.

For example, in the present embodiment, by measuring the difference between the rise time or the fall time of the measured signal V_{T2} and the measured signal V_{T1} by the TDC 200, the above-described phase error θ (delay time) can be detected. Moreover, in the present embodiment, the phase difference (delay time) of the signal between the terminals 312 and 322 can be detected by performing an operation of the difference between the detected phase errors θ (delay times). Then, in the present embodiment, by performing correction using the phase error θ and the phase difference (delay time) detected by the high-resolution TDC 200, the distance measurement accuracy of the distance measuring device 1 can be improved. The detailed configuration of the TDC 200 and the time measuring method according to the present embodiment will be sequentially described in detail below.

### 4.2 Delay Signal Generation Unit 208

As described above, the TDC 200 according to the present embodiment includes the delay signal generation unit 208. Therefore, a detailed configuration of the delay signal generation unit 208 will be described with reference to FIGS. 11 to 16. FIGS. 11 to 16 are explanatory diagrams for explaining an example of a delay signal generation unit 208 according to the present embodiment.

First, an outline of an example of the delay signal generation unit 208 according to the present embodiment will be described with reference to FIG. 11. For example, as illustrated in FIG. 11, the delay signal generation unit 208 can include selectors 400a, 400b that select signals to be output, and a generator 410 that generates a delay signal V_{T1D}. Specifically, the selector 400 a selects a delay signal generated from the generator 410 as described later, and outputs the delay signal to a terminal a. Furthermore, the selector 400b selects a signal to be measured by the TDC 200 from the plurality of measured signals V_{T2} that can be the above-described measurement target, and outputs the selected signal to a terminal b. The terminals a, b are electrically connected to the pulse generator 202 described above, and signals selected by the selectors 400a, 400b are output to the pulse generator 202.

Then, as described above, in order to make the output load uniform, the generator 410 may include, for example, a plurality of flip-flop circuits (not illustrated) arranged in a line and evenly on a semiconductor substrate (not illustrated). Alternatively, as similar to the above, the generator 410 may include, for example, a plurality of latch circuits (not illustrated) arranged in a line and evenly on a semiconductor substrate (not illustrated). Note that a detailed configuration of the generator 410 will be described later.

Moreover, the generator 410 is electrically connected to the reference clock signal source 420. Specifically, the reference clock signal CLK is supplied to a plurality of flip-flop circuits or latch circuits included in the generator 410 by wiring branched in a tournament form from the reference clock signal source 420 such that the reference clock signal CLK is uniformly supplied without variation in delay time.

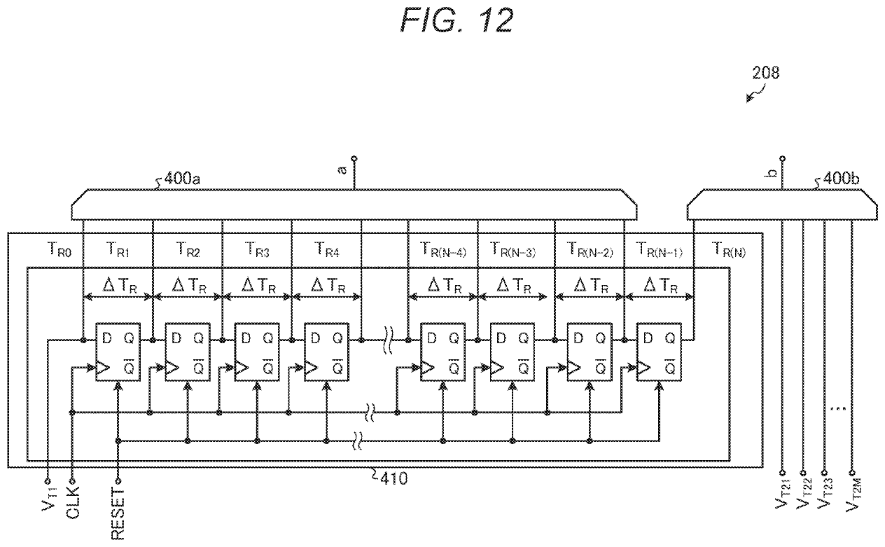

For example, the generator 410 may include a plurality of D-type flip-flop circuits connected in series as illustrated in FIG. 12. The D-type flip-flop circuit acquires a signal input to an input terminal D, and outputs the acquired signal to an output terminal Q according to the rising edge of the reference clock signal CLK input to the clock input terminal. Specifically, the measured signal V_{T1} is input to the flip-flop circuit of the first stage, and the delay signal (T_{R1} to T_{RN} in FIG. 12) generated in the preceding stage is sequentially input to the flip-flop circuit of each stage. Moreover, the reference clock signal CLK is input to each flip-flop circuit. Furthermore, each flip-flop circuit delays the input measured signal V_{T1} or the delay signals (T_{R1} to T_{RN}) input from the flip-flop circuit at the preceding stage by one clock cycle T_{CLK} (corresponding to ΔT_{R} in FIG. 12) on the basis of the rising of the reference clock signal CLK input to each flip-flop circuit, and newly generates delay signals (T_{R1} to T_{RN}). The signal (T_{R0} and the generated delay signals (T_{R1} to T_{R(N-1)}) are input to the selector 400a. Then, the selector 400a described above selects one delay signal from the signal (T_{R0}) and the generated delay signals (T_{R1} to T_{R(N-1)}) on the basis of the delay amount (RG value) determined by the delay evaluation unit 206, and outputs the selected delay signal to the pulse generator 202. Accordingly, in the present embodiment, the measurement range of the TDC 200 is limited by the number of stages of the flip-flop circuits included in the generator 410. Note that, in the present embodiment, the flip-flop circuit of the generator 410 may be configured to output a signal acquired according to the falling edge of the reference clock signal CLK to the output terminal Q, and output an inverted signal of the acquired signal to an inverted output terminal Q (underlined Q).

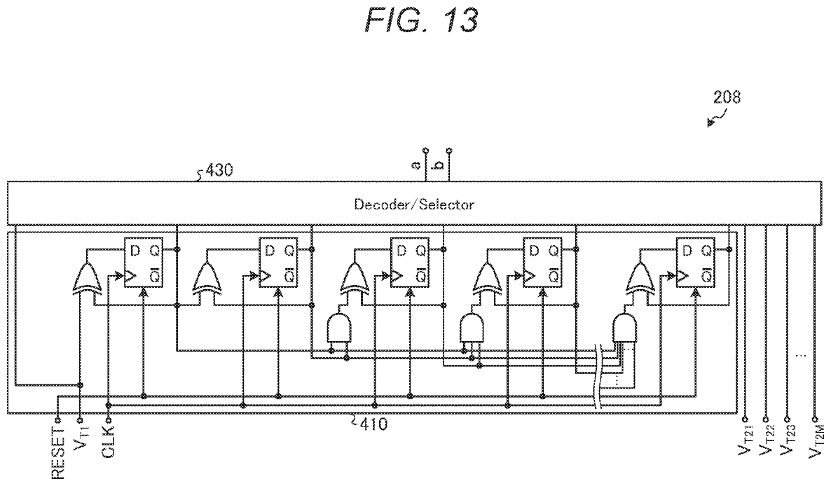

Furthermore, as illustrated in FIG. 13, the generator 410 may reduce the number of flip-flop circuits by combining a plurality of flip-flop circuits with a logic circuit (AND, EOR) to form a counter circuit. By reducing the number of flip-flop circuits in this manner, the area of the chip on which the circuit of the TDC 200 is formed can be reduced, and an increase in manufacturing cost can be suppressed. Note that, in the delay signal generation unit 208 illustrated in FIG. 13, a decoder/selector 430 is used instead of the selectors 400a, 400b.

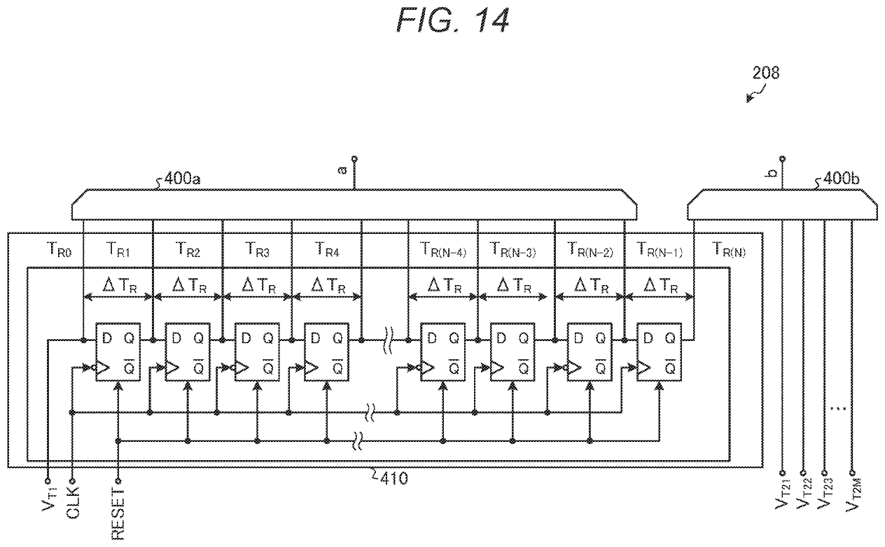

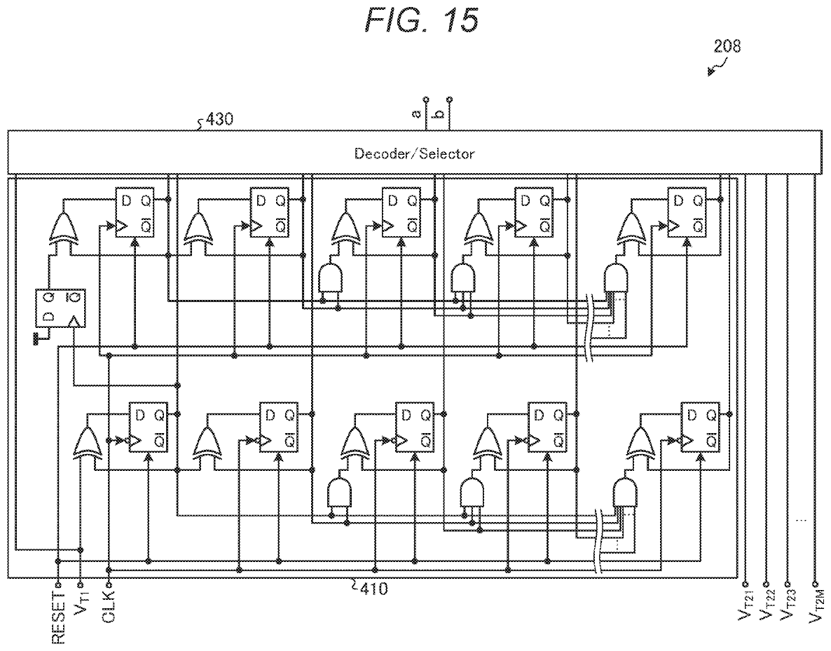

Furthermore, for example, as illustrated in FIG. 14, the generator 410 may change the configuration illustrated in FIG. 12 so as to invert the reference clock signal CLK and input the inverted signal to some flip-flop circuits. As a result, since the delay signal can be generated at fine intervals using both the rising edge and the falling edge of the reference clock signal CLK, the time resolution of the fine measurement unit 210 can be further improved, and the input range of the signal to the fine measurement unit 210 can be narrowed. As similar to this, for example, as illustrated in FIG. 15, the generator 410 may change the configuration illustrated in FIG. 13 so as to invert the reference clock signal CLK and input the inverted signal to some flip-flop circuits.

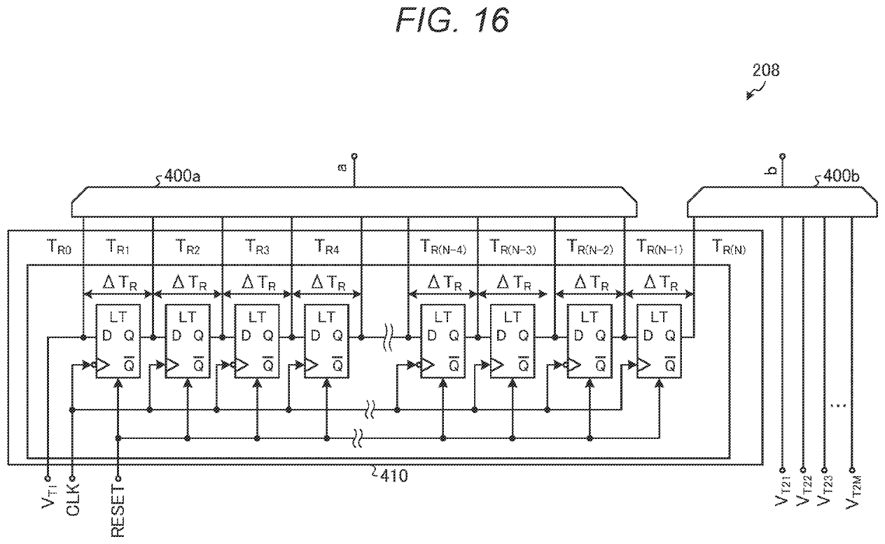

Furthermore, for example, as illustrated in FIG. 16, the generator 410 may replace a plurality of flip-flop circuits in the configuration illustrated in FIG. 12 with a plurality of D-type latch circuits that hold states. In a case where the reference clock signal CLK input to the clock input terminal is at the HIGH level, the D-type latch circuit outputs the signal input to the input terminal D to the output terminal Q, and in a case where the reference clock signal CLK is at the LOW level, the D-type latch circuit maintains the previously input signal. By replacing the flip-flop circuits with the latch circuits in this manner, the area of the chip on which the circuit of the TDC 200 is formed can be reduced, and an increase in manufacturing cost can be suppressed. Moreover, power consumption can be suppressed. Note that, in this configuration, when the HIGH section of the positive clock input to the latch circuit and the LOW section of the negative clock overlap, the signal passes through, and thus it is preferable to take measures.

### 4.3 Time Measuring Method

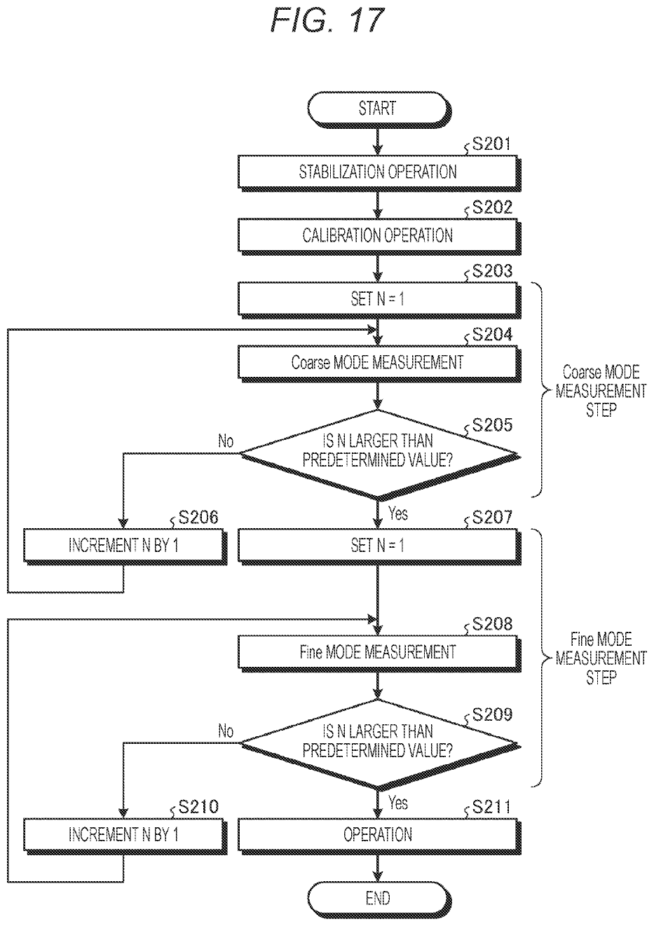

Next, details of the time measuring method of the TDC 200 according to the present embodiment will be described with reference to FIG. 17. FIG. 17 is a flowchart for explaining a time measuring method of a TDC 200 according to the present embodiment. Specifically, as illustrated in FIG. 17, the time measuring method according to the present embodiment includes a plurality of steps from step S201 to step S211. Details of each step included in the time measuring method according to the present embodiment will be described below.

First, in the present embodiment, the TDC 200 is activated, and the signal supply is repeated a predetermined number of times until the voltage of the signal (drive pulse) supplied from the above-described control unit 40 to each functional unit such as the TDC 200 is stabilized at a predetermined value (step S201). Next, a calibration operation of the TDC 200 is performed (step S202). Note that details of the calibration operation according to the present embodiment will be described later.

Next, the Cosrse mode measurement illustrated in FIG. 7 is performed. As illustrated in FIG. 17, the Cosrse mode measurement includes steps S203 to S206. First, the number of measurements N is set to 1 (step S203). Then, the TDC 200 obtains the measured pulse V_{T2-T1} described above in increments of a clock cycle T_{CLK} of the reference clock signal CLK, generates a digital timing signal V_{CS}, and counts (coarsely measures) the digital timing signal V_{CS} in the reference clock cycle T_{CLK} (step S204).

Moreover, the TDC 200 determines whether the number of measurements N is larger than a predetermined value set in advance (step S205). In the present embodiment, it is preferable to improve the accuracy by repeating the measurement until the value becomes larger than a predetermined value and adopting, for example, an average value of values obtained by the measurement.

Accordingly, the predetermined value is preferably set to be large, but if the predetermined value is set to be large, the measurement time becomes long, and thus it is preferable to appropriately adjust the predetermined value according to the required distance measurement accuracy and the like. The TDC 200 proceeds to the processing of step S207 in a case where the number of measurements N is larger than the predetermined value (step S205: Yes), and proceeds to the processing of step S206 in a case where the number of measurements N is not larger than the predetermined value (step S205: No). Then, the TDC 200 increments the number of times of measurement N by 1, and the process returns to step S204 (step S206).

Next, the fine mode measurement illustrated in FIG. 7 is performed. As illustrated in FIG. 17, the fine mode measurement includes steps S207 to S210. First, the number of measurements N is set to 1 (step S207). First, the TDC 200 generates a delay signal V_{T1D} by delaying the measured signal V_{T1} by a numerical value obtained by multiplying the delay amount (RG value) proportional to the width of the measured pulse V_{T2-T1} based on the count result of the Cosrse mode measurement by the reference clock cycle T_{CLK}. Next, the TDC 200 converts a difference in rise time or fall time between the delay signal V_{T1D} and the measured signal V_{T2} into a difference V_{FN}. Moreover, the TDC 200 measures the difference V_{FN} with high resolution (step S208).

Moreover, the TDC 200 determines whether the number of measurements N is larger than a predetermined value set in advance (step S209). In the present embodiment, it is preferable to improve the accuracy by repeating the measurement until the value becomes larger than a predetermined value and adopting, for example, an average value of values obtained by the measurement. The TDC 200 proceeds to the processing of step S211 in a case where the number of measurements N is larger than the predetermined value (step S209: Yes), and proceeds to the processing of step S210 in a case where the number of measurements N is not larger than the predetermined value (step S209: No). Then, the TDC 200 increments the number of times of measurement N by 1, and the process returns to step S208 (step S210).

Next, the TDC 200 performs an operation of a difference (measurement target T_{MEAS}) between rise times or fall times of the two measured signals V_{T1} and V_{T2} by using the count result of the Coarse mode measurement and the measurement result of the fine measurement (step S211). Specifically, the TDC 200 integrates the time width of the difference V_{FN} that is the measurement result of the fine measurement mode with respect to the multiplication of the delay amount (RG) based on the count result of the Cosrse mode measurement and the reference clock cycle T_{CLK}, and ends the time measuring method according to the present embodiment. Note that, in the present embodiment, the predetermined value to be compared with the number of times of measurement N in each step described above may be the same or different from each other in each step. Furthermore, in FIG. 17, the calibration operation (step S202) is performed after the stable operation (step S201), but the present embodiment is not limited thereto, and the calibration operation may be performed at any timing after the stable operation (step S201).

As described above, in the present embodiment, the fine measurement unit 210 measures the difference V_{FN} between the delay signal V_{T1D} generated by delaying the measured signal V_{T1} by a numerical value obtained by multiplying the delay amount (RG value) proportional to the width of the measured pulse V_{T2-T1} by the reference clock cycle T_{CLK}, and the above-described measured signal V_{T2}. The difference V_{FN} is a difference between the V_{T1D} and the measured signal V_{T2} generated in this manner, and thus has a width equal to or less than the reference clock cycle T_{CLK}. Accordingly, in the present embodiment, since the measurement range of the fine measurement unit 210 including the TV conversion circuit 100 can be narrowed to a width equal to or less than the reference clock cycle T_{CLK}, the time resolution of the fine measurement unit 210 can be improved. As a result, in the present embodiment, the time resolution of the TDC 200 can be improved.

### 5. Second Embodiment

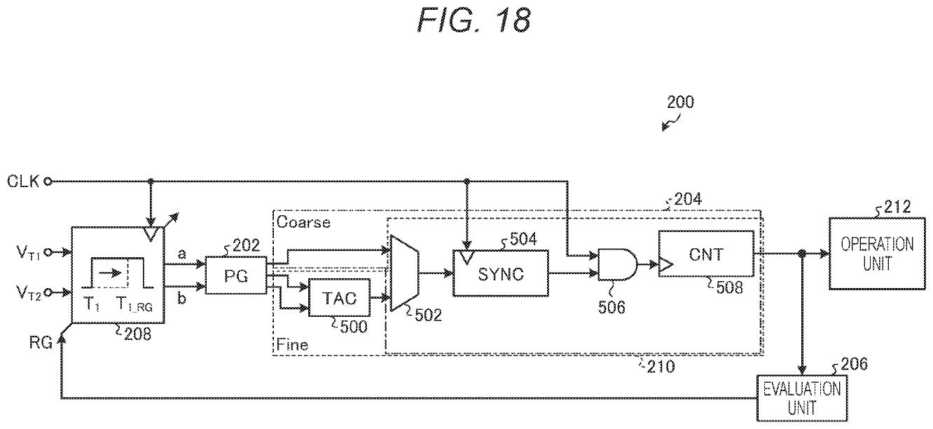

Next, the TDC 200 according to the first embodiment is modified as described below to eliminate the need for the ADC 106 having high resolution, and the counter 508 (see FIG. 18) is shared between the Coarse measurement unit 204 and the fine measurement unit 210, so that the circuit configuration of the TDC 200 can be made compact and an increase in manufacturing cost can be suppressed. Such an embodiment will be described below as a second embodiment of the present disclosure.

### 5.1Configuration Example of TDC 200

First, a configuration example of the TDC 200 according to the present embodiment will be described with reference to FIG. 18. FIG. 18 is an explanatory diagram for explaining a configuration example of the TDC 200 according to the present embodiment. Specifically, as similar to the first embodiment, the TDC 200 according to the second embodiment of the present disclosure mainly includes a pulse generator 202, a Coarse measurement unit 204, a delay evaluation unit 206, a delay signal generation unit 208, a fine measurement unit 210, and an operation unit 212. Moreover, the Coarse measurement unit 204 includes a selector 502, a synchronization circuit 504, an AND circuit 506, and a counter 508. Furthermore, the fine measurement unit 210 includes a TV conversion unit (TAC) 500, a selector 502 shared with the Coarse measurement unit 204, a synchronization circuit 504, an AND circuit 506, and a counter 508. Each component of the TDC 200 will be sequentially described, but the description of parts common to the first embodiment will be omitted here.

(TAC 500)

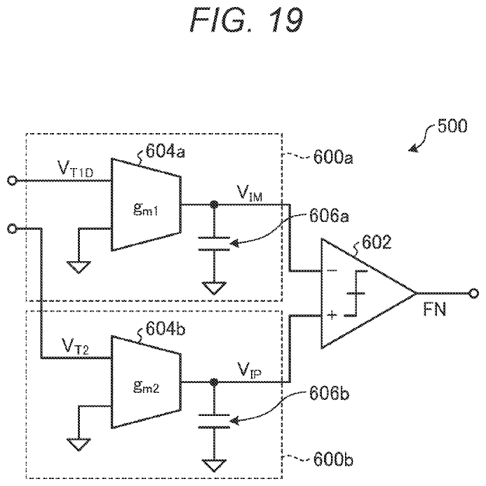

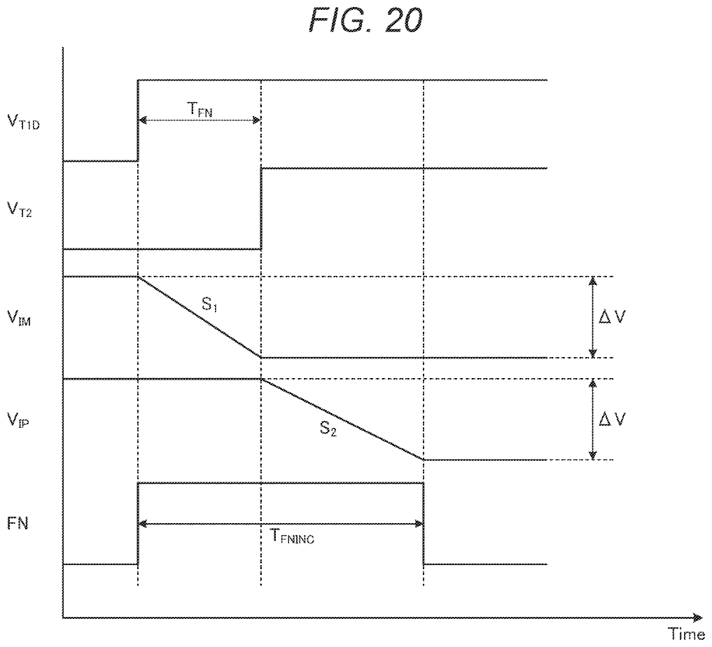

TAC 500 includes two TV conversion circuits 600a, 600b and a comparator 602 (see FIG. 19), and enlarges the difference V_{FN} to perform the Fine measurement mode. Specifically, the TAC 500 receives as an input the delay signal V_{T1D} and the measured signal V_{T2} from the pulse generator 202 to the TAC 500, and the difference V_{FN} (difference time) between the delay signal V_{T1D} and the measured signal V_{T2} is enlarged to generate an enlarged difference FN (see FIG. 20). Note that details of the TAC 500 will be described later.

(Selector 502)

The selector 502 selects either a signal from the pulse generator 202 (measured pulse V_{T2-T1}) or a signal from the TAC 500 (enlarged difference FN) (see FIG. 20) according to whether to perform the Coarse mode measurement or the fine measurement mode, and outputs the selected signal to the synchronization circuit 504 described later.

(Synchronization Circuit 504)

The synchronization circuit 504 obtains a signal (measured pulse V_{T2-T1}, enlarged difference FN) from the selector 502 in increments of a clock cycle T_{CLK} of the reference clock signal CLK, generates a digital timing signal V_{CS}, and outputs the digital timing signal V_{CS} to an AND circuit 506 as described later.

(AND Circuit 506)

The AND circuit 506 receives the reference clock signal CLK and the signal output from the synchronization circuit 504 as inputs, and outputs the signal to the counter 508 when the two inputs are HIGH.

(Counter 508)

The counter 508 counts the signal output from the AND circuit in the clock cycle T_{CLK}, and outputs the count result to the delay evaluation unit 206 and the operation unit 212. Note that, in the present embodiment, the counter 508 counts a signal (measured pulse V_{T2-T1}) from the pulse generator 202 in the Coarse mode measurement, and counts a signal (enlarged difference FN) from the TAC 500 in the fine mode measurement. That is, in the present embodiment, the counter 508 is shared between the Coarse measurement unit 204 and the fine measurement unit 210.

### 5.2 Configuration Example of TAC 500

Next, a configuration example of the TAC 500 according to the present embodiment will be described with reference to FIG. 19. FIG. 19 is an explanatory diagram for explaining a configuration example of the TAC 500 according to the present embodiment. Specifically, as illustrated in FIG. 19, the TAC 500 includes two TV conversion circuits 600a, 600b and a comparator 602. Each component of the TAC 500 will be sequentially described below.

(TV Conversion Circuits 600a, 600b)

Each of TV conversion circuits 600a, 600b includes an integrator including Gm amplifiers 604a, 604b and capacitors 606a, 606b, has integral slopes (S₁, S₂) (see FIG. 20) different from each other, and outputs voltages at different timings. Specifically, a delay signal V_{T1D} is input from the pulse generator 202 to the TV conversion circuit 600a, and a voltage V_{IM} according to a change in the input signal is output. Furthermore, a measured signal V_{T2} is input from the pulse generator 202 to the TV conversion circuit 600b, and a voltage V_{IP} according to a change in the input signal is output. Note that the Gm amplifiers 604a, 604b may be charge pumps (not illustrated) including a current source and a switch.

(Comparator 602)

The comparator 602 compares the voltage V_{IM} output from the TV conversion circuits 600a, 600b with the voltage V_{IP}, and when the voltage V_{IM} is smaller than the voltage V_{IP}, outputs a signal (enlarged difference) FN (see FIG. 20), so that the difference V_{FN} can be enlarged. Note that, in the present embodiment, the input width (dynamic range) of the comparator 602 is preferably designed to fall within a predetermined range.

Note that the comparator 602 may malfunction due to input of noise or the like from a power supply (not illustrated) after initialization, and even if malfunction occurs for about several nanoseconds, offset or variation occurs in a signal (enlarged difference) FN, which causes a distance measurement error. Therefore, in order to prevent such a malfunction of the comparator 602, it is preferable to control the comparator 602 using the reference clock signal CLK or the like so that the activation (rising) of the comparator 602 after being initialized is delayed by a predetermined time from the rising time of the input delay signal V_{T1D}. By such a control, since the comparator 602 can secure a sufficient time to be activated after initialization, the comparator 602 shifts to a stable state, and is activated from such a stable state, so that it is less likely to be affected by noise or the like. As a result, in the present embodiment, since a malfunction of the comparator 602 can be prevented, an offset or variation hardly occurs in the signal (enlarged difference) FN, and thus, it is possible to avoid occurrence of a distance measurement error.

### 5.3 Configuration Example of TAC 500

Next, the operation of the TAC 500 according to the present embodiment will be described with reference to FIG. 20. FIG. 20 is an example of a timing chart of the TAC 500 according to the present embodiment. Note that, in FIG. 20, a difference between rise times or fall times of two measured signals V_{T1} and V_{T2} to be measured is defined as T_{FN}.

First, the delay signal V_{T1D} and the measured signal V_{T2} illustrated in the first and second rows from the top in FIG. 20 are input to each of the TV conversion circuits 600a, 600b of the TAC 500. Then, the TV conversion circuit 600 a outputs a voltage V_{IM} having a gradient of an integral slope S₁ and a voltage difference (height) ΔV according to a change in the input delay signal V_{T1D} (third row from the top in FIG. 20). Furthermore, the TV conversion circuit 600b outputs a voltage V_{IP} having a gradient of an integral slope S₂ and a voltage difference (height) ΔV according to a change in the input measured signal V_{T2} (fourth row from the top in FIG. 20).

Moreover, the comparator 602 compares the voltage V_{IM} output from the TV conversion circuits 600a, 600b with the voltage V_{IP}, and outputs a signal (enlarged difference) FN (fifth row from the top in FIG. 20). Then, the output time width T_{FNINC} of the FN is counted in the clock cycle T_{CLK} by the synchronization circuit 504 and the counter 508 of the Coarse measurement unit 204 described above.

The measurement target T_{FN} can be expressed as the following Equation (7) on the basis of Equation (1).

$$\begin{matrix}[ Math . 7 ] & \\ {T}_{FN} = \frac{Δ V}{{S}_{1}} & ( 7 )\end{matrix}$$

Then, the time width T_{FNINC} of the enlarged difference FN can be expressed by the following Equation (8) on the basis of the Equations (1) and (7).

$$\begin{matrix}[ Math . 8 ] & \\ \begin{matrix}{T}_{FNINC} = \frac{Δ V}{{S}_{1}} + \frac{Δ V}{{S}_{2}} \\ = \frac{{S}_{1} + {S}_{2}}{{S}_{2}} * {T}_{FN}\end{matrix} & ( 8 )\end{matrix}$$

Moreover, since the time width T_{FNINC} of the enlarged difference FN is counted in the clock cycle T_{CLK}, the time width T_{FNINC} can be expressed by the following Equation (9).

[Math. 9]

T_{FNICN}=T_{CLK}*CNT (9)

Then, since the measurement target T_{FN} can be expressed by the following Equation (10) by the Equations (8) and (9), the measurement target T_{FN} can be calculated by the time width T_{FNINC} of the enlarged difference FN.

$$\begin{matrix}[ Math . 10 ] & \\ {T}_{FN} = \frac{{S}_{2}}{{S}_{1} + {S}_{2}} * {T}_{CLK} * CNT & ( 10 )\end{matrix}$$

Furthermore, as can be seen from the Equation (10), the measurement target T_{FN} is measured with resolution determined from the integral slopes S₁, S₂ and the clock cycle T_{CLK}, and specifically, is measured with high resolution equal to or less than the reference clock cycle T_{CLK}. Then, since the resolution is determined by the ratio of the integral slopes S₁ and S₂ according to Equation (10), it can be seen that the resolution is robust against voltage variation and temperature variation.

As described above, in the present embodiment, by using the two TV conversion circuits 600a, 600b, the comparator 602, and the Coarse measurement unit 204 instead of the TV conversion circuit 100 and the ADC 106 of the fine measurement unit 210 of the TDC 200 according to the first embodiment described above, it is possible to eliminate the need for the ADC 106 having high resolution. Moreover, in the present embodiment, the fine measurement unit 210 shares a counter circuit with the Coarse measurement unit 204. As a result, in the present embodiment, the circuit configuration of the TDC 200 can be made compact, and an increase in manufacturing cost can be suppressed.

Moreover, in the present embodiment, since the measurement resolution of the measurement target T_{FN} is determined by the ratio of the integral slopes S₁, S₂, it can be seen that the resolution is robust against voltage variation and temperature variation. Furthermore, in the present embodiment, in the measurement in the fine measurement mode, the measurement target T_{FN} is not measured as it is, but the measurement is performed by enlarging the measurement target T_{FN} to the time width T_{FNINC} of the enlarged difference FN.

Note that, also in the present embodiment, a generator 410 capable of generating a delay signal at fine intervals using both rising and falling edges of the reference clock signal (CLK) as illustrated in FIG. 14 may be used. In this case, for example, the configurations of the synchronization circuit 504, the AND circuit 506, and the counter 508 illustrated in FIG. 18 are divided into two configurations of a block using a rising edge of the reference clock signal CLK and a block using a falling edge of the reference clock signal CLK. Furthermore, in order not to degrade the measurement accuracy, it is preferable that an interval of a counter (not illustrated) that counts with a rising of the reference clock signal CLK as a reference and an interval of a counter (not illustrated) that counts with a falling of the reference clock signal CLK as a reference coincide with a Duty of the reference clock signal CLK. Moreover, the Duty of the reference clock signal CLK can be measured by measuring a rising edge and a falling edge of the pulse signal for calibration (details will be described later) generated by the delay signal generation unit 208.

### 5.4 Modification

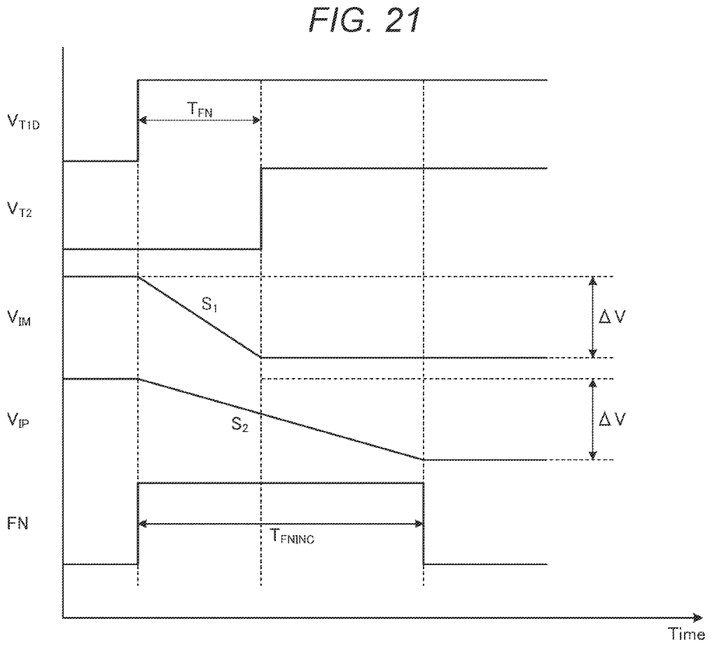

Moreover, the present embodiment may be modified as illustrated in FIG. 21. FIG. 21 is an example of a timing chart of the TAC 500 according to a modification of the present embodiment.

Specifically, in the present modification, each of the TV conversion circuits 600a, 600b has an integral slope (S₁, S₂) (see FIG. 20) different from each other, and as illustrated in FIG. 21, the TV conversion circuits may be simultaneously activated unlike the second embodiment described above. As a result, according to the present modification, since the number of switches of the circuit constituting the TDC 200 can be reduced, it is possible to achieve high-speed measurement.

Specifically, according to the Equation (7), the time width T_{FNINC} of the enlarged difference FN can be expressed by the following Equation (11).

$$\begin{matrix}[ Math . 11 ] & \\ \begin{matrix}{T}_{FNINC} = \frac{Δ V}{{S}_{2}} \\ = \frac{{S}_{1}}{{S}_{2}} * {T}_{FN}\end{matrix} & ( 11 )\end{matrix}$$

Then, since the measurement target T_{FN} can be expressed by the following Equation (12) by the Equation (9), the measurement target T_{FN} can be calculated by the time width T_{FNINC} of the enlarged difference FN.

$$\begin{matrix}[ Math . 12 ] & \\ {T}_{FN} = \frac{{S}_{2}}{{S}_{1}} * {T}_{CLK} * CNT & ( 12 )\end{matrix}$$

Furthermore, in the present modification, as can be seen from Equation (12), although the resolution is deteriorated as compared with the present embodiment, since the measurement target T_{FN} is measured with the resolution determined from the integral slopes S₁, S₂ and the clock cycle T_{CLK}, the measurement target T_{FN} is measured with high resolution equal to or less than the reference clock cycle T_{CLK}. Then, in the present modification, since the measurement resolution of the measurement target T_{FN} is determined by the ratio of the integral slopes S₁, S₂, it can be seen that the resolution is robust against voltage variation and temperature variation. Note that, in the present modification, the integral slope S₁ is preferably sufficiently larger than the integral slope S₂, and as a result, the resolution can be further improved.

### 6. Third Embodiment

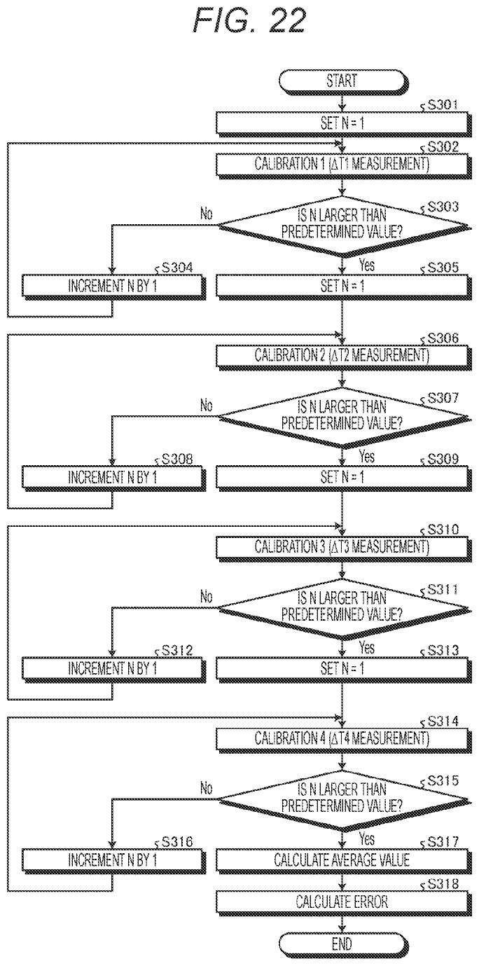

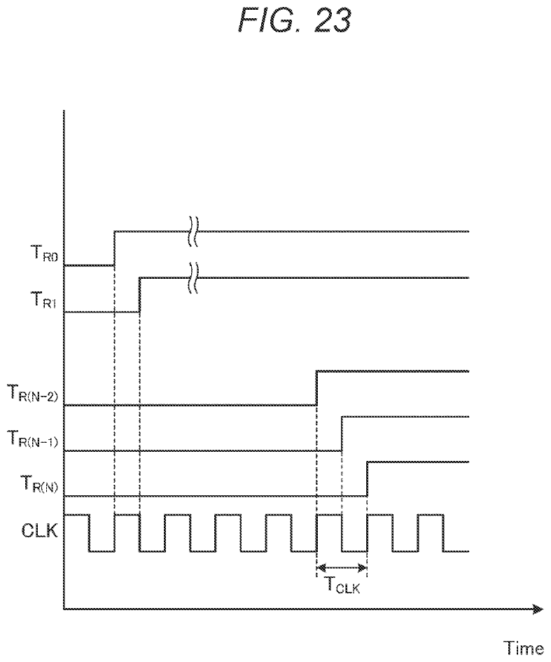

In the first and second embodiments described above, it is preferable to calibrate the TDC 200 in order to improve the measurement accuracy of the TDC 200. Therefore, calibration of the TDC 200 will be described as a third embodiment of the present disclosure with reference to FIGS. 22 to 24. FIG. 22 is a flowchart for explaining the calibration method according to the present embodiment, and FIGS. 23 and 24 are explanatory diagrams for explaining the calibration method according to the present embodiment.

Specifically, in the present embodiment, time widths of a plurality of known pulse signals (pulse signals for calibration) are measured, and the TDC 200 is calibrated on the basis of the measurement result. As illustrated in FIG. 22, the calibration method according to the present embodiment includes a plurality of steps from step S301 to step S318. Details of each step included in the calibration method according to the present embodiment will be described below.

Note that, here, a generator 410 capable of generating a delay signal at fine intervals using both rising and falling edges of the reference clock signal (CLK) as illustrated in FIG. 14 is used. Note that the present embodiment is not limited to using such a generator 410.

First, for example, in the calibration method described below, the time widths of at least two known pulse signals generated using the reference clock signal CLK are measured. For example, a T_{R(N)} signal in FIG. 23 generated by the generator 410 is input to the fine measurement unit 210 as the measured signal V_{T2}, and a T_{R(N-1)} signal in FIG. 23 generated by the generator 410 is input to the fine measurement unit 210 as the measured signal V_{T1}, and thereby a pulse signal having a time width of 0.5 cycles of the clock cycle T_{CLK} can be measured. Moreover, for example, the T_{R(N)} signal in FIG. 23 is input to the fine measurement unit 210 as the measured signal V_{T2}, and a T_{R(N-2)} signal in FIG. 23 is input to the fine measurement unit 210 as the measured signal V_{T1}, and thereby a pulse signal having a time width of 1cycle of the clock cycle T_{CLK} can be measured. Therefore, in the calibration according to the present embodiment, for example, four pulse signals having a time width of two cycles from 0.5 cycles of the clock cycle T_{CLK} are measured. In the present embodiment, a pulse signal to be measured for calibration is generated using an output of the generator 410 from a flip-flop circuit at a subsequent stage or a final stage that is not used for measurement. Accordingly, according to the present embodiment, since the load of each flip-flop circuit included in the generator 410 is made uniform by electrically connecting the flip-flop circuit to the selector 400b, the accuracy of the intervals (differences between the delay signals) of the plurality of delay signals to be generated can be further improved.

Then, the TDC 200 performs measurement related to a signal having a pulse width for 0.5 cycles of the clock cycle T_{CLK}. Next, the TDC 200 sets the number of calibrations N to 1 (step S301). Then, the TDC 200 generates a pulse width for 0.5 cycles of the clock cycle T_{CLK} of the reference clock signal CLK and measures (counts) a time width of the generated pulse width (calibration 1) (step S302). The coordinates (ΔT₁, ΔTₒᵤₜ₁) plotted on the graph illustrated in FIG. 24 are calculated on the basis of the measurement result (count output value CNT₁).

Moreover, the TDC 200 determines whether the number of calibrations N is larger than a predetermined value set in advance (step S303). In the present embodiment, it is preferable to improve the accuracy of the calibration by repeating the calibration until the value becomes larger than a predetermined value and adopting, for example, an average value of values obtained by the calibration. Accordingly, the predetermined value is preferably set to be large, but if the predetermined value is set to be large, the calibration time becomes long, and thus it is preferable to appropriately adjust the predetermined value according to the required distance measurement accuracy and the like. The TDC 200 proceeds to the processing of step S305 in a case where the number of calibration N is larger than the predetermined value (step S303: Yes), and proceeds to the processing of step S304 in a case where the number of calibration N is not larger than the predetermined value (step S303: No). Then, the TDC 200 increments the number of times of calibrations N by 1, and the process returns to step S302 (step S304).

Next, the TDC 200 performs measurement related to a signal having a pulse width for 1.5 cycles of the clock cycle T_{CLK}. Note that steps S305 to S308 in FIG. 22 are the same as steps S301 to S304 described above except that the time width is measured (counted) with respect to the pulse width of 1.5 cycles of the clock cycle T_{CLK}, and thus, description thereof is omitted here. Note that the coordinates (ΔT₂, ΔTₒᵤₜ₂) plotted on the graph illustrated in FIG. 24 are calculated on the basis of the measurement result (count output value CNT₂).

Then, the TDC 200 performs measurement related to a signal having a pulse width for 1 cycle of the clock cycle T_{CLK}. Note that steps S309 to S312 in FIG. 22 are the same as steps S301 to S304 described above except that the time width is measured (counted) with respect to the pulse width of 1 cycle of the clock cycle T_{CLK}, and thus, description thereof is omitted here. Note that the coordinates (ΔT₃, ΔTₒᵤₜ₃) plotted on the graph illustrated in FIG. 24 are calculated on the basis of the measurement result (count output value CNT₃).

Moreover, the TDC 200 performs measurement related to a signal having a pulse width for 2 cycles of the clock cycle T_{CLK}. Note that steps S313 to S316 in FIG. 22 are the same as steps S301 to S304 described above except that the time width is measured (counted) with respect to the pulse width of 2 cycles of the clock cycle T_{CLK}, and thus, description thereof is omitted here. Note that the coordinates (ΔT₄, ΔTₒᵤₜ₄) plotted on the graph illustrated in FIG. 24 are calculated on the basis of the measurement result (count output value CNT₄).

Next, the TDC 200 calculates an average value of the count output values CNTₙ obtained as a result of measuring a plurality of times (step S317). Moreover, the TDC 200 calculates a gradient TG (time gain) and an offset time T_{offset} illustrated in FIG. 24 as errors (step S318). The gradient TG (time gain) and the offset time T_{offset} calculated in this manner can be used when correcting (calibrating) the measurement result of the TDC 200. Specifically, ΔTₒᵤₜₙ in FIG. 24 can be obtained from the average value of the count output values CNTₙ by the following Equation (13).

$$\begin{matrix}[ Math . 13 ] & \\ Δ {T}_{outn} = \frac{{T}_{CLK}}{2} * \overline{{CNT}_{n}} & ( 13 )\end{matrix}$$

$$( n = 1 , 2 , 3 , 4 )$$

Then, the gradient TG (time gain) can be obtained from the average value of the count output values CNTₙ by the following Equation (14).

$$\begin{matrix}[ Math . 14 ] & \\ TG = \frac{Δ {T}_{out 2} - Δ {T}_{out 1}}{Δ {T}_{2} - Δ {T}_{1}} = \frac{1}{2} * ( \overline{{CNT}_{2}} - \overline{{CNT}_{1}} ) & ( 14 )\end{matrix}$$

Moreover, the offset time T_{offset} can be obtained from the average value of the count output values CNTₙ by the following Equation (15).

$$\begin{matrix}[ Math . 15 ] & \\ {T}_{offset} = Δ {T}_{out 3} - TG * Δ {T}_{3} = \frac{{T}_{CLK}}{2} * \{ \overline{{CNT}_{3}} - ( \overline{{CNT}_{2}} - \overline{{CNT}_{1}} ) \} & ( 15 )\end{matrix}$$

Then, the calibration method according to the present embodiment ends. Note that, in the present embodiment, the measurement of the time width of the pulse signal is not necessarily performed in the order described above (Equations (13) to (15) described above follow the order of measurement described above). Furthermore, the present embodiment is not limited to measuring the time widths of the four known pulse signals, and for example, the present embodiment may be configured to measure the time widths of three known pulse signals, and is not particularly limited as long as the time widths of at least two known pulse signals are measured.

As described above, in the present embodiment, time widths of a plurality of known pulse signals (pulse signals for calibration) are measured, and the TDC 200 is calibrated on the basis of the measurement result, so that the measurement accuracy of the TDC 200 can be improved.

### 7. Fourth Embodiment

In the above description, the TDC 200 has been described as being used in the distance measuring device 1, but the TDC 200 is not limited to such use. For example, in a CMOS image sensor (not illustrated), a common column signal processing unit (not illustrated) is provided for each of a plurality of pixels arranged in the column direction. The column signal processing unit includes an integrated ADC that performs signal processing such as analog-degital (A/D) conversion on the pixel signal output from the pixel and outputs an output signal (for example, Patent Document 2 described above).

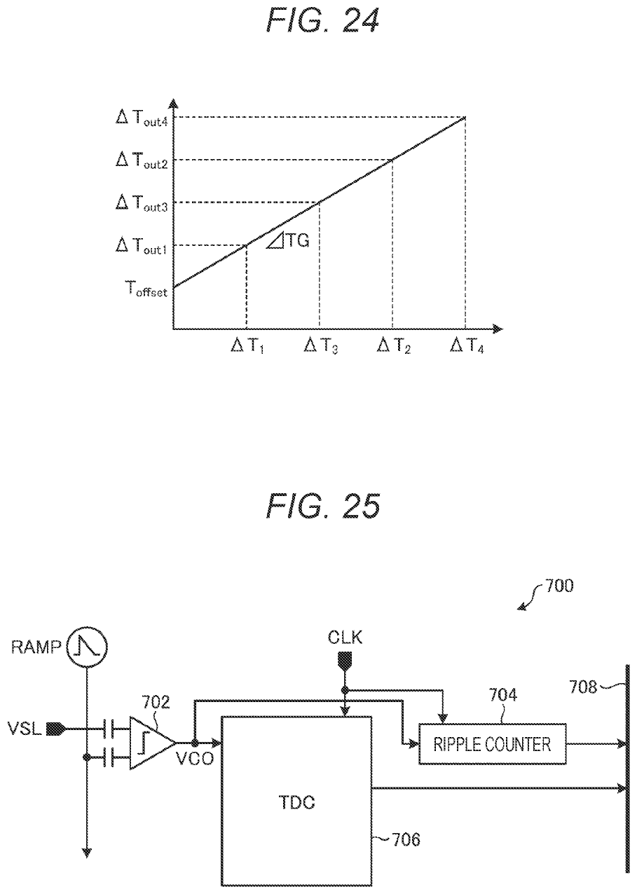

Specifically, the integrated ADC described above can be configured as illustrated in FIG. 25, for example. FIG. 25 is an explanatory diagram for explaining a configuration example of an ADC 700 according to the present embodiment. As illustrated in FIG. 25, the ADC 700 includes a comparator 702, a ripple counter 704 as a counter, a TDC 706, and a transfer bus 708. The comparator 702 compares the voltage of the ramp waveform (RAMP) whose voltage value linearly changes with time with the input voltage VSL, and outputs a signal VCO having a level according to the comparison result to the ripple counter 704 and the TDC 706. Moreover, the ripple counter 704 counts the time width of the signal on the basis of the reference clock signal CLK. Moreover, the TDC 706 can be the TDC 200 in the present embodiment, and measures the time width of the signal with a resolution finer than the clock cycle T_{CLK} of the reference clock signal CLK. Moreover, the ripple counter 704 and the TDC 706 output respective measurement results to the transfer bus 708.

As described above, the TDC 200 according to the present embodiment can be used in a column signal processing unit (not illustrated) of a CMOS image sensor (not illustrated). Note that the TDC 200 is not limited to such use, and may be provided in another device as long as the device is required to perform time measurement with high resolution.

### 8. Conclusion

As described above, in the present embodiment of the present disclosure, the time resolution of the TDC 200 can be improved. Specifically, in the present embodiment, the fine measurement unit 210 measures the difference V_{FN} between the delay signal V_{T1D} generated by delaying the measured signal V_{T1} by a numerical value obtained by multiplying the delay amount (RG value) proportional to the width of the measured pulse V_{T2-T1} by the reference clock cycle T_{CLK}, and the above-described measured signal V_{T2}. The difference V_{FN} is a difference between the V_{T1D} and the measured signal V_{T2} generated in this manner, and thus has a width equal to or less than the reference clock cycle T_{CLK}. Accordingly, in the present embodiment, since the measurement range of the fine measurement unit 210 including the TV conversion circuit 100 can be narrowed to a width equal to or less than the reference clock cycle T_{CLK}, the time resolution of the fine measurement unit 210 can be improved. As a result, in the present embodiment, the time resolution of the TDC 200 can be improved.

### 9. Supplement

Each step in the time measuring method according to the embodiment described above does not necessarily have to be processed in the described order. For example, each step may be processed in a changed order as appropriate. Furthermore, instead of being processed in chronological order, each step may be processed partly in parallel or separately. Moreover, the processing of each step does not necessarily have to be processed according to the described method, and for example, may be processed by other methods by other functional blocks.

Moreover, at least a part of the time measuring method according to the embodiment described above can be configured by software as an information processing program that causes a computer to function. In a case where the time measuring method is configured by software, a program that achieves at least a part of these methods may be stored in a recording medium and read and executed by the distance measuring device 1 or the like or another device connected to the distance measuring device 1. Furthermore, the program that achieves at least a part of the time measuring method may be distributed via a communication line (including wireless communication) such as the Internet. Moreover, the program may be distributed via a wired line or a wireless line such as the Internet or stored in a recording medium in an encrypted, modulated, or compressed state.

While preferred embodiments of the present disclosure have been described above in detail with reference to the accompanying drawings, the technical scope of the present disclosure is not limited to such examples. It is obvious that various variations and modifications can be conceived within the scope of the technical idea described in the claims by a person having ordinary knowledge in the field of technology to which the present disclosure belongs, and, of course, it is understood that these variations and modifications belong to the technical scope of the present disclosure.

Furthermore, the effects described in the present specification are merely illustrative or exemplary, and are not limitative. That is, the technique according to the present disclosure can exhibit other effects obvious to those skilled in the art from the description of the present specification together with the effects described above or instead of the effects described above.

Note that, the present technology can also adopt the following configuration.

(1)

A time measuring device including:

a first counter unit that acquires a difference time between a first measured signal and a second measured signal as a first measurement result by counting on the basis of a reference clock signal;

a delay signal generation unit that generates a delay signal by delaying the first measured signal on the basis of the first measurement result fed back from the first counter unit;

a measurement unit that measures a difference time between the delay signal and the second measured signal as a second measurement result; and

an operation unit that performs an operation by using the first measurement result and the second measurement result.

(2)

The time measuring device according to (1), in which the first counter unit acquires, as the first measurement result, a difference time between a rise time or a fall time of the first measured signal having a substantially rectangular wave and a rise time or a fall time of the second measured signal having a substantially rectangular wave.

(3)

The time measuring device according to (2), in which the measurement unit measures, as the second measurement result, a difference time between a rise time or a fall time of the delay signal having a substantially rectangular wave and the rise time or the fall time of the second measured signal.

(4)

The time measuring device according to any one of (1) to (3), in which the delay signal generation unit generates the delay signal on the basis of a delay amount proportional to a value of the first measurement result.

(5)

The time measuring device according to any one of (1) to (4),

in which the delay signal generation unit includes

a plurality of flip-flop circuits arrayed in a line and evenly on a semiconductor substrate.

(6)

The time measuring device according to any one of (1) to (4),

in which the delay signal generation unit includes

a plurality of latch circuits arrayed in a line and evenly on a semiconductor substrate.

(7)

The time measuring device according to (5), in which each of the plurality of flip-flop circuits is electrically connected to wiring branched from a reference clock signal source in a tournament form.

(8)

The time measuring device according to (7), in which the delay signal generation unit generates the delay signal using a rising edge or a falling edge of the reference clock signal having a substantially rectangular wave.

(9)

The time measuring device according to (7), in which the delay signal generation unit generates the delay signal using a rising edge and a falling edge of the reference clock signal having a substantially rectangular wave.

(10)

The time measuring device according to (7), in which the delay signal generation unit generates a signal for calibration using the reference clock signal.

(11)

The time measuring device according to any one of (1) to (10), in which the measurement unit includes a time-voltage conversion circuit and an analog-digital conversion circuit.

(12)

The time measuring device according to any one of (1) to (10), in which the measurement unit includes a first time-voltage conversion circuit and a second time-voltage conversion circuit having different slopes, a comparator, and a second counter unit.

(13)

The time measuring device according to (12),

in which the comparator enlarges the difference time between the delay signal and the second measured signal on the basis of output signals from the first time-voltage conversion circuit and the second time-voltage conversion circuit to which the delay signal and the second measured signal are input, and

the second counter unit measures the difference time that has been enlarged, by counting the difference time on the basis of the reference clock signal.

(14)

The time measuring device according to (12) or (13), in which the measurement unit includes the first counter unit functioning as the second counter unit.

(15)

The time measuring device according to any one of (12) to (14), in which the first time-voltage conversion circuit and the second time-voltage conversion circuit are activated at different timings.

(16)

The time measuring device according to any one of (12) to (14), in which the first time-voltage conversion circuit and the second time-voltage conversion circuit are activated simultaneously.

(17)

A time measuring method including:

acquiring a difference time between a first measured signal and a second measured signal as a first measurement result by counting on the basis of a reference clock signal;

generating a delay signal by delaying the first measured signal on the basis of the first measurement result that has been fed back;

measuring a difference time between the delay signal and the second measured signal as a second measurement result; and

performing an operation by using the first measurement result and the second measurement result.

(18)

A distance measuring device that is a ToF distance measuring device including a time measuring device,

the time measuring device including:

a first counter unit that acquires a difference time between a first measured signal and a second measured signal as a first measurement result by counting on the basis of a reference clock signal;

a delay signal generation unit that generates a delay signal by delaying the first measured signal on the basis of the first measurement result fed back from the first counter unit;

a measurement unit that measures a difference time between the delay signal and the second measured signal as a second measurement result; and

an operation unit that performs an operation by using the first measurement result and the second measurement result.

(19)

The distance measuring device according to (18), which is an indirect ToF distance measuring device that performs distance measurement on the basis of a phase difference.

### REFERENCE SIGNS LIST

1 Distance measuring device

20 Irradiation unit

30 Light receiving unit

40 Control unit

60 Processing unit

100, 600a, 600b TV conversion circuits

102, 202 Pulse generator

104 Integrator

106, 700 ADC

108 Delay device

200, 706 TDC

204 Coarse measurement unit

206 Delay evaluation unit

208 Delay signal generation unit

210 Fine measurement unit

212 Operation unit

300 Pixel drive pulse generator

302, 312, 322 Terminal

310 Laser drive pulse generator

320 Pixel unit

400a, 400b, 502 Selector

410 Generator

420 Reference clock signal source

430 Decoder/selector

500 TAC

504 Synchronization circuit

506 AND circuit

508 Counter

602, 702 Comparator

604a, 604b Gm amplifier

606a, 606b Capacitor

704 Ripple counter

708 Transfer bus

800 Object

802a, 802b Region

1. A time measuring device comprising:
a first counter unit that acquires a difference time between a first measured signal and a second measured signal as a first measurement result by counting on a basis of a reference clock signal;
a delay signal generation unit that generates a delay signal by delaying the first measured signal on a basis of the first measurement result fed back from the first counter unit;
a measurement unit that measures a difference time between the delay signal and the second measured signal as a second measurement result; and
an operation unit that performs an operation by using the first measurement result and the second measurement result.

2. The time measuring device according to claim 1, wherein the first counter unit acquires, as the first measurement result, a difference time between a rise time or a fall time of the first measured signal having a substantially rectangular wave and a rise time or a fall time of the second measured signal having a substantially rectangular wave.

3. The time measuring device according to claim 2, wherein the measurement unit measures, as the second measurement result, a difference time between a rise time or a fall time of the delay signal having a substantially rectangular wave and the rise time or the fall time of the second measured signal.

4. The time measuring device according to claim 1, wherein the delay signal generation unit generates the delay signal on a basis of a delay amount proportional to a value of the first measurement result.

5. The time measuring device according to claim 1,
wherein the delay signal generation unit includes
a plurality of flip-flop circuits arrayed in a line and evenly on a semiconductor substrate.

6. The time measuring device according to claim 1,
wherein the delay signal generation unit includes
a plurality of latch circuits arrayed in a line and evenly on a semiconductor substrate.

7. The time measuring device according to claim 5, wherein each of the plurality of flip-flop circuits is electrically connected to wiring branched from a reference clock signal source in a tournament form.

8. The time measuring device according to claim 7, wherein the delay signal generation unit generates the delay signal using a rising edge or a falling edge of the reference clock signal having a substantially rectangular wave.

9. The time measuring device according to claim 7, wherein the delay signal generation unit generates the delay signal using a rising edge and a falling edge of the reference clock signal having a substantially rectangular wave.

10. The time measuring device according to claim 7, wherein the delay signal generation unit generates a signal for calibration using the reference clock signal.

11. The time measuring device according to claim 1, wherein the measurement unit includes a time-voltage conversion circuit and an analog-digital conversion circuit.

12. The time measuring device according to claim 1, wherein the measurement unit includes a first time-voltage conversion circuit and a second time-voltage conversion circuit having different slopes, a comparator, and a second counter unit.

13. The time measuring device according to claim 12,
wherein the comparator enlarges the difference time between the delay signal and the second measured signal on a basis of output signals from the first time-voltage conversion circuit and the second time-voltage conversion circuit to which the delay signal and the second measured signal are input, and
the second counter unit measures the difference time that has been enlarged, by counting the difference time on a basis of the reference clock signal.

14. The time measuring device according to claim 12, wherein the measurement unit includes the first counter unit functioning as the second counter unit.

15. The time measuring device according to claim 12, wherein the first time-voltage conversion circuit and the second time-voltage conversion circuit are activated at different timings.

16. The time measuring device according to claim 12, wherein the first time-voltage conversion circuit and the second time-voltage conversion circuit are activated simultaneously.

17. A time measuring method comprising:
acquiring a difference time between a first measured signal and a second measured signal as a first measurement result by counting on a basis of a reference clock signal;
generating a delay signal by delaying the first measured signal on a basis of the first measurement result that has been fed back;
measuring a difference time between the delay signal and the second measured signal as a second measurement result; and
performing an operation by using the first measurement result and the second measurement result.

18. A distance measuring device that is a ToF distance measuring device comprising a time measuring device,
the time measuring device including:
a first counter unit that acquires a difference time between a first measured signal and a second measured signal as a first measurement result by counting on a basis of a reference clock signal;
a delay signal generation unit that generates a delay signal by delaying the first measured signal on a basis of the first measurement result fed back from the first counter unit;
a measurement unit that measures a difference time between the delay signal and the second measured signal as a second measurement result; and
an operation unit that performs an operation by using the first measurement result and the second measurement result.

19. The distance measuring device according to claim 18, which is an indirect ToF distance measuring device that performs distance measurement on a basis of a phase difference.
